(19) United States
(12) Patent Application Publication
(10) Pub. No.: US 2012/0146077 A1
(43) Pub. Date: Jun. 14, 2012

(54) LIGHT EMITTING DEVICE

(76) Inventors: Koji Nakatsu, Kagoshima (JP); Koichi Nakahara, Kagoshima (JP); Toshihide Maeda, Kagoshima (JP); Toshirou Kitazono, Kagoshima (JP); Isamu Yonekura, Kagoshima (JP)

(21) Appl. No.: 13/391,070

(22) PCT Filed: Aug. 20, 2010
(86) PCT No.: PCT/JP2010/005155

§ 371 Date: Feb. 17, 2012

(30) Foreign Application Priority Data
Aug. 21, 2009 (JP) 2009-191562
Oct. 15, 2009 (JP) 2009-238069
Mar. 25, 2010 (JP) 2010-069648

(51) Int. Cl. H01L 33/50

(52) U.S. Cl. 257/98; 257/E33.061

(57) ABSTRACT

A light emitting device 1 includes a wiring substrate 4 on which a light emitting element 2 is mounted, a sealing section 5 containing a phosphor and sealing the light emitting element 2, a light diffusion section 7 provided on the sealing section 5 and containing particles for diffusing light emitted from the light emitting element 2, and a light reflection section 6 provided so as to cover part of the sealing section 5 other than a top surface of the sealing section 5 and reflecting light emitted from the light emitting element 2. In the light diffusion section 7, silicone dioxide which is a diffusing material is contained in a transparent medium which is a base material. In the light reflection section 6, titanium dioxide which is a reflective material is contained in a transparent medium which is a base material.

### TECHNICAL FIELD

The present invention relates to a light emitting device in which a phosphor is contained in a sealing section for sealing a light emitting element.

### BACKGROUND ART

A light emitting device in which a phosphor is contained in a sealing section for sealing a light emitting element has been known. The phosphor is excited by light emitted from the light emitting element, thereby emitting light having a converted wavelength. Light toward outside has a color mixture of the light emitted from the light emitting element and the light having the wavelength converted by the phosphor. Thus, the phosphor is contained in the sealing section, thereby obtaining desired light different from light emitted from the light emitting element.

A semiconductor light emitting device of Patent Document 1 has been known as the light emitting device in which the phosphor is contained in the sealing section. In the semiconductor light emitting device described in Patent Document 1, a flip-chip light emitting element is conductively mounted on a submount element, and the light emitting element is sealed in a resin package containing a fluorescent material for wavelength conversion. The thickness of the package from an outer surface of the light emitting element is substantially uniform in all of light emitting directions of the light emitting element, and therefore the degree of wavelength conversion by the fluorescent material can be uniformized in all of the light emitting directions of the light emitting element.

### CITATION LIST

### Patent Document

PATENT DOCUMENT 1: Japanese Patent Publication No. 2001-135861
PATENT DOCUMENT 2: Japanese Patent Publication No. 2007-288125
PATENT DOCUMENT 3: Japanese Patent Publication No. 2008-166782
PATENT DOCUMENT 4: Japanese Patent Publication No. 2008-239677

### SUMMARY OF THE INVENTION

### Technical Problem

However, in the semiconductor light emitting device described in Patent Document 1, since an arc surface is defined at each of corners of the package in order to substantially uniformize the thickness of the package from the outer surface of the light emitting element in all of the light emitting directions of the light emitting element, it is assumed that molding of the package is difficult.

Thus, a technique is desired, by which a light emitting device with less color unevenness can be formed so as to have a simple configuration.

It is an objective of the present invention to provide a light emitting device with less color unevenness, which includes an easily-formable sealing section containing a phosphor and sealing a light emitting element.

### Solution to the Problem

A light emitting device of the present invention include a light emitting element mounted on a base; and a sealing section configured to seal the light emitting element and containing a phosphor. A light diffusion section containing particles for diffusing light emitted from the light emitting element is provided on the sealing section.

### Advantages of the Invention

In the light emitting device of the present invention, since the light diffusion section is provided on the sealing section, light emitted from the light emitting element is diffused by the light diffusion section, thereby reducing color unevenness.

### BRIEF DESCRIPTION OF THE DRAWINGS

FIG. 1 is a plan view illustrating a light emitting device of a first embodiment.

FIG. 2 is a cross-sectional view of the light emitting device illustrated in FIG. 1 along an A-A line.

FIG. 3 is a bottom view of the light emitting device illustrated in FIG. 1.

FIG. 4 is a cross-sectional view illustrating a light emitting element.

FIG. 5 is a plan view illustrating the light emitting element.

FIG. 6 is a circuit diagram illustrating a connection between the light emitting element and a zener diode.

FIGS. 7(a)-7(d) are views illustrating steps for manufacturing the light emitting device illustrated in FIG. 1.

FIGS. 8(a)-8(d) are views illustrating steps for manufacturing the light emitting device illustrated in FIG. 1.

FIGS. 9(a) and 9(b) are views illustrating steps for manufacturing the light emitting device illustrated in FIG. 1.

FIG. 10 is a view illustrating a usage state of the light emitting device illustrated in FIG. 2.

FIG. 11 is an xy chromaticity diagram illustrating the color of umber.

FIG. 12 is an enlarged view of part of an xy chromaticity diagram illustrating chromaticity when a red phosphor is mixed with an orange phosphor.

FIG. 13 is an enlarged view of part of an xy chromaticity diagram illustrating chromaticity when a red phosphor is mixed with an orange phosphor.

FIG. 14 is an xy chromaticity diagram.

FIG. 15 is a plan view illustrating a light emitting device of a second embodiment.

FIG. 16 is a cross-sectional view of the light emitting device illustrated in FIG. 15 along an A-A line.

FIG. 17 is a schematic view illustrating a color liquid crystal panel of the second embodiment.

FIGS. 18(a)-18(d) are views illustrating steps for manufacturing the light emitting device illustrated in FIG. 15.

FIGS. 19(a)-19(d) are views illustrating steps for manufacturing the light emitting device illustrated in FIG. 15.

FIGS. 20(a)-20(e) are views illustrating steps for manufacturing the light emitting device illustrated in FIG. 15.

FIG. 21 is a graph illustrating a relationship between an emission wavelength of the light emitting device illustrated in FIG. 15 and a transmission wavelength of a color filter.

FIG. 22 is a plan view of a light emitting device of a third embodiment.

FIG. 23 is a cross-sectional view of the light emitting device illustrated in FIG. 22.

FIG. 24 is a circuit diagram of the light emitting device illustrated in FIG. 22.

FIG. 25 is a cross-sectional view of a light emitting element used for the light emitting device illustrated in FIG. 22.

FIG. 26 is a plan view of the light emitting element used for the light emitting device illustrated in FIG. 22.

FIGS. 27(A)-27(E) are views illustrating steps for manufacturing the light emitting device.

FIG. 28 is a plan view illustrating a light emitting device of a fourth embodiment.

FIG. 29 is a cross-sectional view of the light emitting device illustrated in FIG. 28.

### DESCRIPTION OF EMBODIMENTS

An embodiment of the present invention is directed to a light emitting device of the present invention include a light emitting element mounted on a base; and a sealing section configured to seal the light emitting element and containing a phosphor. A light diffusion section containing particles for diffusing light emitted from the light emitting element is provided on the sealing section.

According to the foregoing embodiment, even in a case where the thickness of the sealing section containing the phosphor is different between an upward direction and a sideward direction of the light emitting element, since the light diffusion section is provided on the sealing section, light emitted from the light emitting element is diffused by the light diffusion section. As a result, the color unevenness can be reduced.

A preferable embodiment of the present invention is directed to the light emitting device in which, in the light diffusion section, silicone dioxide which is a diffusing material is contained in a transparent medium which is a base material.

According to the foregoing embodiment, since the silicone dioxide which is the diffusing material is contained in the transparent medium, the transparent medium functions as the light diffusion section for diffusing light emitted from the light emitting element.

Another preferable embodiment of the present invention is directed to the light emitting device in which a light reflective section configured to reflect light emitted from the light emitting element is provided so as to cover part of the sealing section other than a top surface of the sealing section.

According to the foregoing embodiment, the light reflective section is provided so as to cover the part of the sealing section other than the top surface of the sealing section. Thus, since light traveling toward the part of the sealing section other than the top surface of the sealing section is reflected in the upward direction, brightness in the upward direction can be improved. In addition, since light exiting from the top surface of the sealing section is diffused by the light diffusion section, the entirety of the top surface of the sealing section serves as a light emitting surface with less color unevenness.

Still another embodiment of the present invention is directed to the light emitting device in which, in the light reflective section, titanium dioxide which is a reflective material is contained in a transparent medium which is a base material.

According to the foregoing embodiment, since the titanium dioxide which is the reflective material is contained in the transparent medium, the transparent medium functions as the light reflective section for reflecting light emitted from the light emitting element.

Still another embodiment of the present invention is directed to the light emitting device in which the sealing section is formed such that the thickness of the sealing section in the sideward direction of the light emitting element is larger than the thickness of the sealing section in the upward direction of the light emitting element.

According to the foregoing embodiment, when the thickness of the sealing section in the upward direction of the light emitting element is maintained constant, if the thickness of the sealing section in the sideward direction of the light emitting element is increased, the area of the top surface of the sealing section is expanded. Thus, the large area of the top surface, which is the light emitting surface, of the sealing section can be ensured, thereby increasing a flux of light diffused by the light diffusion section. As a result, the light emitting device can emit brighter light.

### First Embodiment

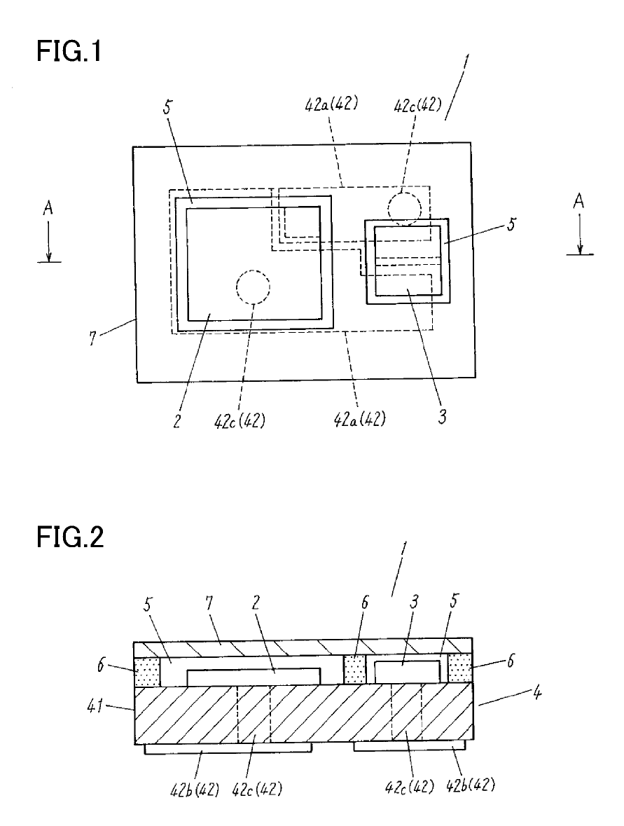

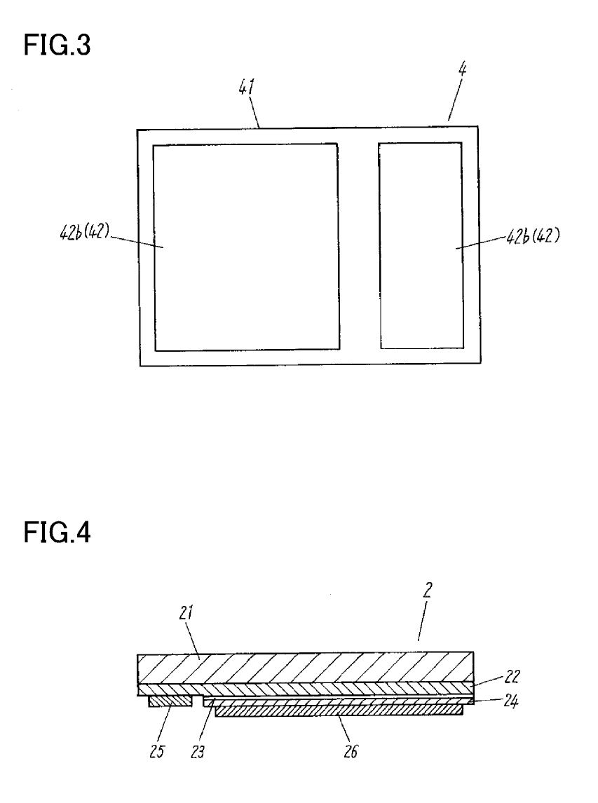

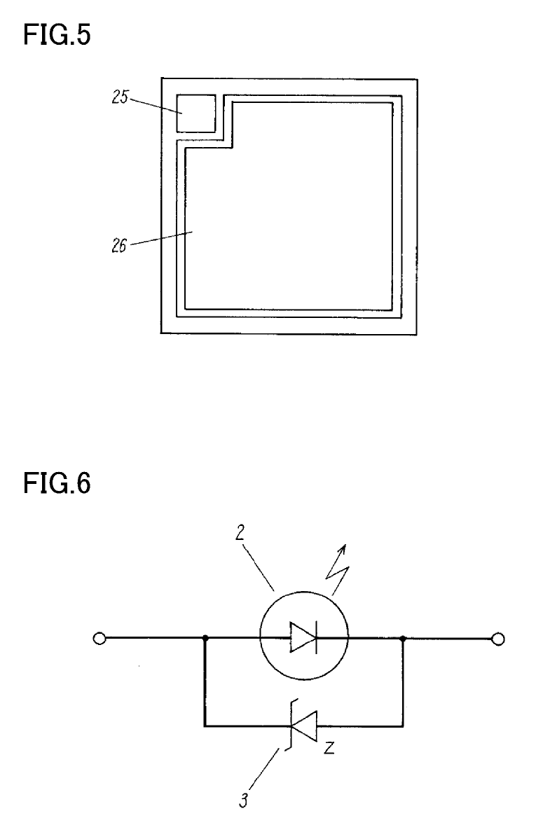

A light emitting device of a first embodiment will be described with reference to drawings. FIG. 1 is a plan view illustrating the light emitting device of the present embodiment. FIG. 2 is a cross-sectional view of the light emitting device illustrated in FIG. 1 along an A-A line. FIG. 3 is a bottom view of the light emitting device illustrated in FIG. 1. FIG. 4 is a cross-sectional view illustrating a light emitting element. FIG. 5 is a plan view illustrating the light emitting element. FIG. 6 is a circuit diagram illustrating a connection between the light emitting element and a zener diode.

As illustrated in FIGS. 1-3, a light emitting device 1 is a light emitting diode (LED) including a light emitting element 2, a zener diode 3, a wiring substrate 4, sealing sections 5, a light reflective section 6, and a light diffusion section 7. The light emitting device 1 is formed in a shape of a rectangular of about 2 mm×1.6 mm so as to have a thickness of about 0.75 mm.

The light emitting element 2 is a flip-chip light emitting diode including a substrate 21, an n-type layer 22, an active layer 23, a p-type layer 24, an n-side electrode 25, and a p-side electrode 26.

The substrate 21 functions to hold a semiconductor layer including the n-type layer 22, the active layer 23, and the p-type layer 24. Sapphire having insulating properties may be used as the material of the substrate 21. However, since gallium nitride (GaN) is a base material of a light emitting part considering light emitting efficiency, GaN, SiC, AlGaN, or AlN having the same refractive index as that of a light emitting layer is preferably used in order to reduce light reflection at an interface between the n-type layer 22 and the substrate 21.

The n-type layer 22, the active layer 23, and the p-type layer 24 which are light emitting layers are stacked in this order on the substrate 21. It is preferable that the material of the light emitting layers is a gallium nitride compound. Specifically, the n-type layer 22, the active layer 23, and the p-type layer 24 are made of GaN, InGaN, and GaN, respectively. Note that AlGaN or InGaN may be used for the n-type layer 22 or the p-type layer 24. A buffer layer made of GaN or InGaN may be formed between the n-type layer 22 and the substrate 21. The active layer 23 may have, e.g., a multi-layer structure (quantum well structure) in which an InGaN layer and a GaN layer are alternately stacked.

Part of the n-type layer 22 is exposed by removing part of the n-type layer 22, part of the active layer 23, and part of the p-type layer 24 which are stacked on the substrate 21, and the n-side electrode 25 is provided on the exposed part of the n-type layer 22. Note that, if a substrate is a conductive member, part of the substrate may be exposed and an n-side electrode may be directly provided on the exposed part of the substrate.

The p-side electrode 26 is provided on the p-type layer 24. That is, since part of the n-type layer 22 is exposed by removing part of the active layer 23 and part of the p-type layer 24, the light emitting layers, the p-side electrode 26, and the n-side electrode 25 are provided on the same side relative to the substrate 21.

The p-side electrode 26 is an electrode made of, e.g., Ag, Al, or Rh having high reflectivity in order to reflect light emitted from the light emitting layers toward the substrate 21.

In order to reduce contact resistance between the p-type layer 24 and the p-side electrode 26, an electrode layer made of, e.g., Pt, Ni, Co, or ITO is preferably formed between the p-type layer 24 and the p-side electrode 26. The n-side electrode 25 may be made of, e.g., Al or Ti. In order to increase bonding strength, Au or Al is preferably used on surfaces of the p-side electrode 26 and the n-side electrode 25. Such electrodes may be formed by, e.g., vacuum deposition, sputtering, or ion plating.

The entire area of the light emitting element 2 may be large in order to increase a light amount, and the length of one side of the light emitting element 2 is preferably equal to or greater than 600 μm.

Note that the flip-chip light emitting element has been described in detail as the light emitting element 2, but other types of light emitting elements may be used.

The zener diode 3 functions as a protective element which is, as illustrated in FIG. 6, connected in parallel to the light emitting element 2 so as to have an inverted polarity of the light emitting element 2 and therefore prevents excessive voltage application to the light emitting element 2. The zener diode 3 is provided in a p-type semiconductor region formed in part of an n-type silicone substrate. In the present embodiment, the zener diode 3 has been described as the protective element, but the protective element may be a diode, a capacitor, a resistor, or a varistor.

The wiring substrate 4 is a printed circuit board functioning as a base, i.e., an insulating substrate 41 in which a wiring pattern 42 is formed. The wiring pattern 42 includes top electrodes 42a provided on a mounting surface of the wiring substrate 4, bottom electrodes 42b provided on a surface of the wiring substrate 4 opposite to the mounting surface of the wiring substrate 4, and through-hole electrodes 42c each connecting the top electrode 42a and the bottom electrode 42b together. The insulating substrate 41 may be a glass epoxy resin substrate, a BT resin (thermosetting resin such as bismaleimide triazine resin) substrate, or a ceramic (alumina or aluminum nitride) substrate.

The sealing sections 5 are respectively formed around the light emitting element 2 and the zener diode 3. The sealing section 5 is formed such that the thickness of the sealing section 5 in a sideward direction of the light emitting element 2 is larger than the thickness of the sealing section 5 in an upward direction of the light emitting element 2. The sealing section 5 is formed by dispersing inorganic or organic phosphor particles in a transparent medium which is a base material such as resin or glass. In, e.g., a case where the light emitting element 2 emits blue light and an emission color of the light emitting device 1 itself is white, a phosphor which is excited by receiving blue light from the light emitting element 2 and which converts the wavelength of the blue light to emit yellow light may be employed. As such a phosphor, a rare-earth doped nitride phosphor or a rare-earth doped oxide phosphor is preferred. More specifically, e.g., rare-earth doped alkaline-earth metal sulfide, rare-earth doped garnet of (Y.Sm)₃(Al.Ga)₅O₁₂:Ce or (Y_{0.39}Gd_{0.57}Ce_{0.03}Sm_{0.01})₃Al₅O₁₂, rare-earth doped alkaline-earth metal orthosilicate, rare-earth doped thiogallate, or rare-earth doped aluminate is preferable. Alternatively, a silicate phosphor of (Sr_{1-a1-b2-x}Baₐ₁Ca_{b2}Euₓ)₂SiO₄ or an alpha-sialon phosphor of (α-sialon:Eu)Mx(Si, Al)₁₂(O, N)₁₆ may be used as the phosphor for emitting yellow light.

As the transparent medium, e.g., resin containing silicone resin, epoxy resin, and fluorine resin as main components or a glass material produced by a sol-gel method may be used. Some glass materials have a curing reaction temperature of about 200 degrees Celsius, and the glass material is a preferable material considering heat resistance of materials used for bumps and electrode sections.

The light reflective section 6 is formed by dispersing particles for reflecting light emitted from the light emitting element 2 in a transparent medium which is a base material made of resin such as epoxy resin, acrylic resin, polyimide resin, urea resin, silicone resin, and fluorine resin or made of glass. The light reflective section 6 is formed so as to surround part of the sealing sections 5 respectively sealing the light emitting element 2 and the zener diode 3, other than top surfaces of the sealing sections 5.

The light reflective section 6 can be formed by curing liquid resin containing titanium oxide particles, which are particles for reflecting light and function as a reflective material, and a dispersant. Since the light reflective section 6 is formed by curing the liquid resin containing the titanium oxide powder and the dispersant, insulating properties can be maintained in the light reflection section 6, and a reflex function can be provided to the light reflection section 6. When the light reflective section 6 is formed, a thixotropy imparting agent may be added to the liquid resin for the purpose of enhancing liquidity. As the thixotropy imparting agent, e.g., fine silica powder may be used.

Note that, in the present embodiment, titanium oxide is used as the reflective material, but, e.g., aluminum oxide, silica dioxide, and boron nitride may be used as the reflective material. That is, as long as a material is a metal oxide having the insulating properties and the reflex function, such a material may be used as the reflective material.

In the present embodiment, since the light reflective section 6 contains titanium oxide, the light reflective section 6 has both of light shielding properties and light reflectivity. However, a reflective section may be formed by adding SiO₂ to resin or mixing other metal oxide with resin.

The light diffusion section 7 is formed by dispersing particles for diffusing light emitted from the light emitting element 2 in a transparent medium which is a base material made of resin such as epoxy resin, acrylic resin, polyimide resin, urea resin, silicone resin, and fluorine resin or made of glass. The light diffusion section 7 is formed across the entirety of top surfaces of the sealing sections 5 and the light reflective section 6. SiO₂ particles may be used as the particles for diffusing light emitted from the light emitting element 2.

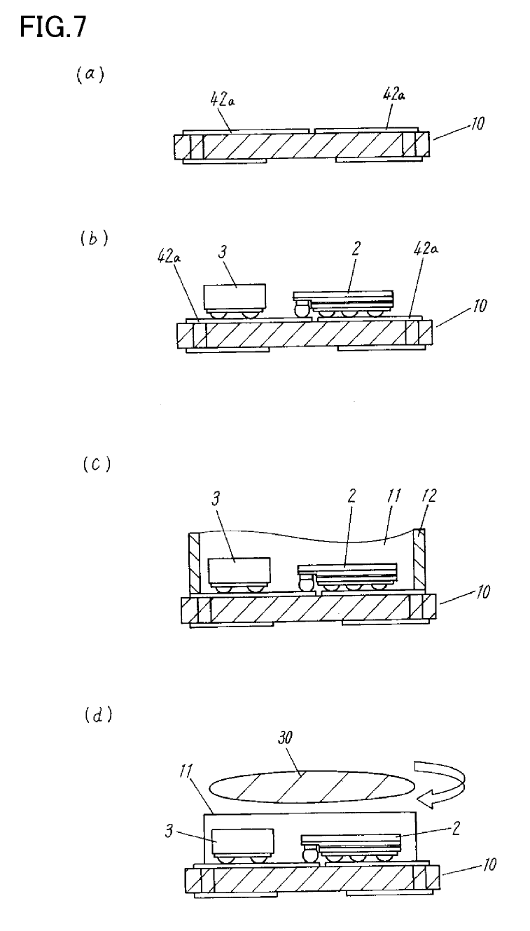

A method for manufacturing the light emitting device of the present embodiment configured as described above will be described with reference to FIGS. 7-9. FIGS. 7-9 are views illustrating steps for manufacturing the light emitting device illustrated in FIG. 1. Note that, in FIGS. 7(a)-9(a), only a single light emitting device is illustrated.

A base material 10 on which wiring substrates 4 are continuously arranged in a matrix is prepared in order to produce a plurality of light emitting devices 1 (see FIG. 7(a)). A light emitting element 2 and a zener diode 3 are mounted on top electrodes 42a formed on the base material 10, respectively (see FIG. 7(b)).

Next, a phosphor layer 11 to be formed into sealing sections 5 for respectively sealing the light emitting element 2 and the zener diode 3 is formed. Printing allows easy formation of the sealing sections 5 in a short time. When the sealing sections 5 are formed by the printing, a printing plate 12 having an opening corresponding to the positions of the light emitting element 2 and the zener diode 3 is arranged. Then, the opening of the printing plate 12 is filled with a transparent medium containing a phosphor and made of resin or glass, and the transparent medium is cured (see FIG. 7(c)).

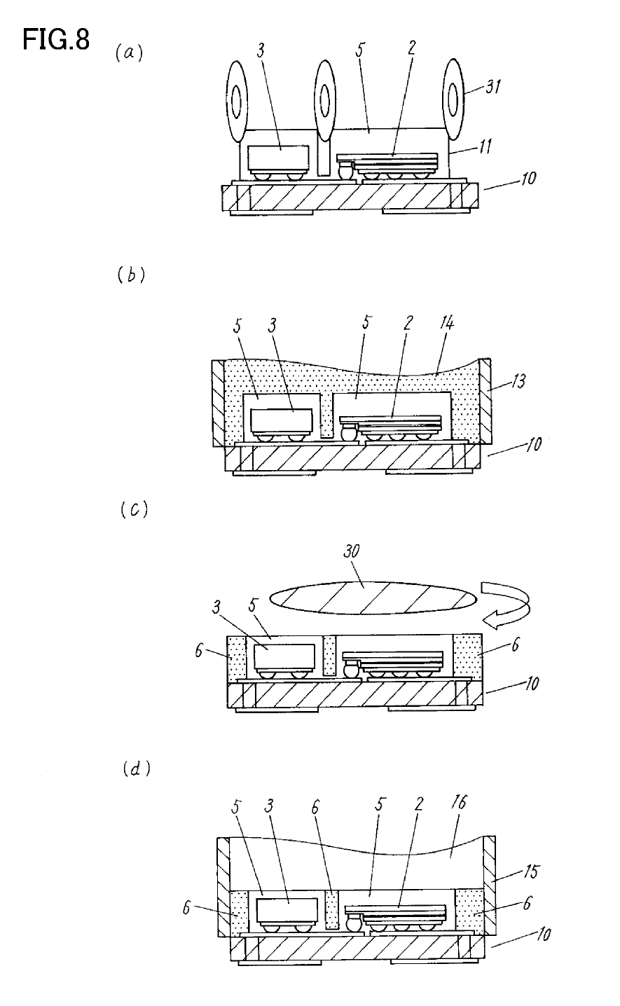

When the phosphor layer 11 is cured, a top surface of the phosphor layer 11 is polished into a smooth surface by a polishing machine 30 (see FIG. 7(d)). Next, the phosphor layer 11 is cut, and then a light reflective section 6 is formed. Positions where the phosphor layer 11 is cut are a position of the phosphor layer 11 between the light emitting element 2 and the zener diode 3, and positions of end portions of the phosphor layer 11 formed by the printing plate 12 (see FIG. 7(c)), i.e., a position of a side portion of the phosphor layer 11 on a side close to the light emitting element 2 and a position of a side portion of the phosphor layer 11 on a side close to the zener diode 3. In such positions, the phosphor layer 11 is cut by a cutting machine 31 such that the cutting machine 31 reaches a mounting surface of the wiring substrate 4 from the top surface of the phosphor layer 11 (see FIG. 8(a)). A groove is formed between the light emitting element 2 and the zener diode 3 by cutting the phosphor layer 11, and both side surfaces of the phosphor layer 11 are smoothed. In such a manner, the phosphor layer 11 is formed into the sealing sections 5.

Next, a printing plate 13 is arranged so as to surround the entirety of the sealing sections 5. An opening of the printing plate 13 is filled with resin or glass in which particles for reflecting light emitted from the light emitting element 2 are dispersed, and the resin or glass is cured. In such a manner, a reflective layer 14 is formed (see FIG. 8(b)).

Then, the entirety of the reflective layer 14 is polished by the polishing machine 30 until the sealing sections 5 are exposed. Since part of the reflective layer 14 is polished until top surfaces of the sealing sections 5 are exposed, the remaining part of the reflective layer 14 serves as the light reflective section 6 (see FIG. 8(c)). Since the groove is formed between the light emitting element 2 and the zener diode 3 in advance, the light reflective section 6 can be formed so as to surround the light emitting element 2. Thus, light emitted from the light emitting element 2 toward side can be reflected by the light reflective section 6 without being blocked by the zener diode 3.

Next, a printing plate 15 having an opening corresponding to the entirety of the polished sealing sections 5 and the polished light reflective section 6 is arranged, and the opening of the printing plate 15 is filled with resin or glass in which particles for reflecting light emitted from the light emitting element 2 are dispersed. In such a manner, a light diffusion layer 16 is formed (see FIG. 8(d)).

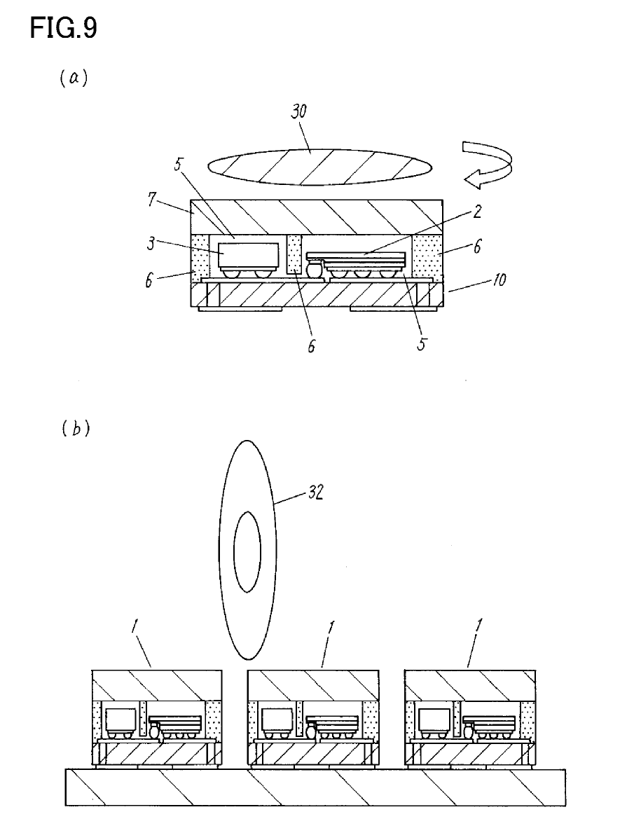

Next, a top surface of the light diffusion layer 16 is polished into a smooth surface by the polishing machine 30, thereby forming the light diffusion layer 16 into a light diffusion section 7 (see FIG. 9(a)). The base material 10 is cut in longitudinal and lateral directions into pieces by a dicer 32 (see FIG. 9(b)). In such a manner, the light emitting device 1 illustrated in FIGS. 1-3 can be produced.

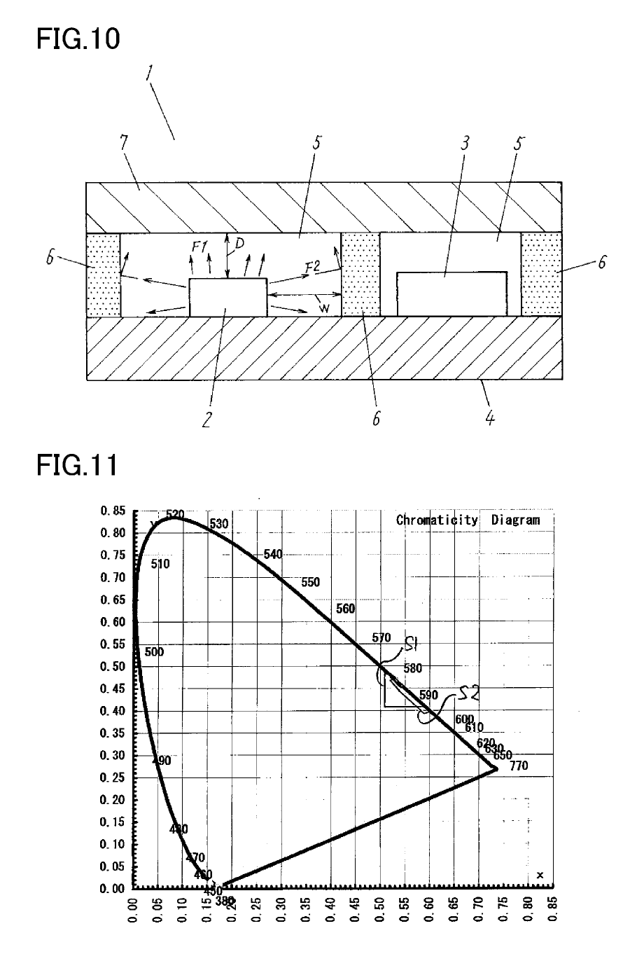

Next, a usage state of the light emitting device of the present embodiment will be described with reference to FIGS. 1-3 and 10. FIG. 10 is a view illustrating the usage state of the light emitting device illustrated in FIG. 2.

First, voltage is applied from the bottom electrode 42b, and then power is supplied to the light emitting element 2 through the through-hole electrode 42c and the top electrode 42a. Then, the light emitting element 2 lights up.

As illustrated in FIG. 10, blue light is emitted from the light emitting element 2 not only in an upward direction F1 of the light emitting element 2 but also in a sideward direction F2 of the light emitting element 2. Light emitted in the upward direction F1 reaches the light diffusion section 7 within a short distance. Light emitted in the sideward direction F2 is reflected by the light reflective section 6 and reaches the light diffusion section 7. Thus, since light emitted in the sideward direction F2 is reflected by the light reflective section 6 and is returned, a distance for which such light travels in the sealing section 5 is increased.

In addition, since the length of the sealing section 5 in the sideward direction F2 is longer than the length of the sealing section 5 in the upward direction F1, the distance for which light reflected by the light reflective section 6 travels in the sealing section 5 is further increased. The transparent medium to be formed into the sealing sections 5 contains the phosphor which is excited by blue light emitted from the light emitting element 2 and which converts the wavelength of the blue light to emit yellow light. Thus, a longer distance for which light travels in the sealing section 5 results in more light emission from the phosphor. As a result, the degree of yellowness is increased. For the foregoing reason, color unevenness which is an increase in degree of yellowness from a portion right above the light emitting element 2 toward periphery is caused at an interface between the sealing section 5 and the light diffusion section 7.

However, in the light emitting device 1 of the present embodiment, the light diffusion section 7 is provided on the sealing sections 5. Thus, light emitted from the light emitting element 2 is diffused by the light diffusion section 7, thereby reducing the color unevenness. As a result, the light emitting device 1 with less color unevenness can be provided. For example, a fine recessed/raised structure is formed in the top surface of the sealing section in order to improve efficiency of light extraction from the light emitting element 2. A fine recessed/raised surface is formed at the top of the sealing section, thereby reducing total reflection of light emitted from the light emitting element 2 by the top surface of the sealing section, which is a light exit surface. However, since the fine recessed/raised surface has low diffusivity, the color unevenness directly appears at the light exit surface. Thus, in order to reduce the color unevenness caused by the phosphor, the light diffusion section 7 containing a diffusing material is preferably provided on the sealing section 5.

Since the length of the sealing section 5 in the sideward direction F2 is longer than the length of the sealing section 5 in the upward direction F1, the large top surface of the sealing section 5 can be ensured. Thus, a high light flux can be obtained.

### First Example

A light emitting device 1 of the present embodiment was produced, and a light flux thereof was measured. Results are shown in Table 1 below. Note that a thickness D of a sealing section 5 in an upward direction of a light emitting element 2 and a thickness W of the sealing section 5 in a sideward direction of the light emitting element 2 were changed, and the thickness W is larger than the thickness D in first to fourth invention samples. For comparison, first and second comparative targets in each of which the thickness W is smaller than the thickness D were produced, and a light flux thereof was measured.

The first and second comparative targets and the first to fourth invention samples are the same except for the thickness of the sealing section sealing the light emitting element 2. The light emitting element 2 which was used is formed in a square shape having a side length of 0.8 mm, and a total light flux was measured by an integrating sphere under measurement conditions which are applied power of 200 mA and a pulse width of 55 msec.

TABLE 1

| | Thickness | Thickness | | |
|---|---|---|---|---|
| | D in | W in | | |
| | Upward | Sideward | Thickness | Light Flux |
| | Direction | Direction | Ratio | [lm] |
| First | 83 μm | 50 μm | 0.60 | 39.2 |
| Comparative Target | | | | |
| Second | 65 μm | 63 μm | 0.97 | 42.3 |
| Comparative Target | | | | |
| First | 49 μm | 70 μm | 1.43 | 44.5 |
| Invention Sample | | | | |
| Second | 45 μm | 100 μm | 2.22 | 44.6 |
| Invention Sample | | | | |
| Third | 44 μm | 130 μm | 2.95 | 47 |
| Invention Sample | | | | |
| Fourth | 43 μm | 170 μm | 3.95 | 47 |
| Invention Sample | | | | |

As is clearly seen from Table 1, in the first to fourth invention samples in which the ratio of the thickness D in the upward direction of the light emitting element 2 to the thickness W in the sideward direction of the light emitting element 2 was 1.43-3.95, the light flux was improved as compared to the comparative targets having the thickness ratios of 0.60 and 0.97. In particular, when the first comparative target is compared with each of the third and fourth invention samples, the light flux was improved by about 20% even in the light emitting element 2 having the same brightness.

(Variation of First Embodiment)

A phosphor is excited by light emitted from a light emitting element, and emits light having a converted wavelength. Light toward outside has a color mixture of the light emitted from the light emitting element and the light having the wavelength converted by the phosphor. A sealing section contains the phosphor, thereby obtaining desired light different from light emitted from the light emitting element.

In, e.g., a light emitting device described in Patent Document 2, a LED chip (light emitting element) for emitting blue light is covered by a phosphor layer in which a yellow phosphor and a red phosphor are mixed/dispersed in transparent resin, thereby realizing white-light emission.

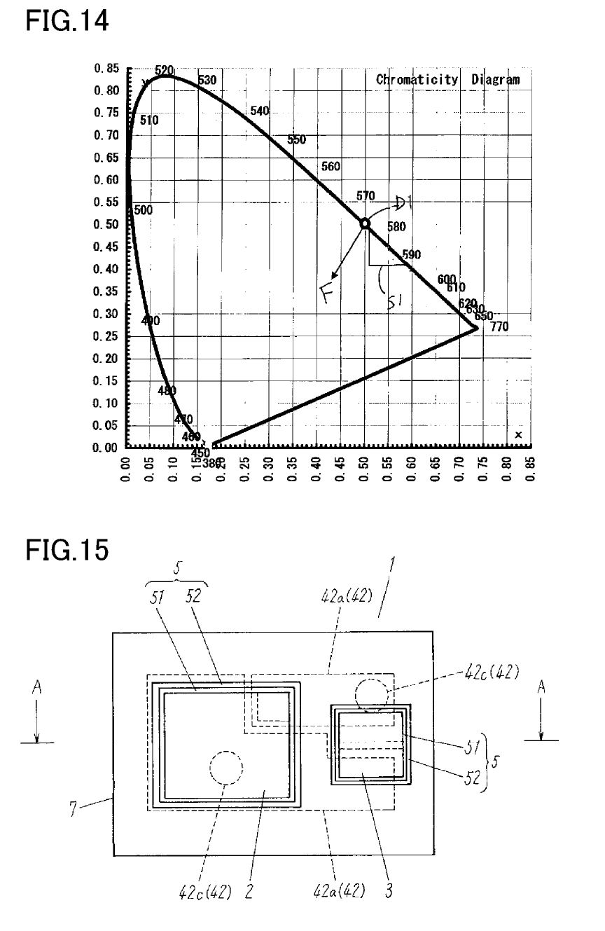

An umber-light emitting device is used for, e.g., a direction indicator of a vehicle or an electronic board. In the umber-light emitting device, a combination of a light emitting element for emitting blue light and a phosphor for emitting orange light is used. In an xy chromaticity diagram illustrated in FIG. 14, the color of umber can be represented by, e.g., values in a range (illustrated as a triangular area S1 in the figure) having x, y coordinates of (0.509, 0.408), (0.509, 0.49), and (0.591, 0.408).

However, there is a variation in blue light among light emitting elements and a variation in orange light among phosphors. Thus, in, e.g., a case where a color mixture of blue light emitted from the light emitting element and orange light emitted from the phosphor is represented by chromaticity values at a point D1, even if the concentration of the phosphor for emitting orange light is adjusted, chromaticity can be adjusted only in an F direction indicated by an arrow in the xy chromaticity diagram. Consequently, the color of umber having good color rendering properties cannot be obtained.

For the foregoing reason, in a variation of the first embodiment, a light emitting element for emitting blue light is used in order to provide a light emitting device from which the color of umber having good color rendering properties can be obtained.

Differences between the first embodiment and the variation of the first embodiment will be described below, and similarities will not be repeated.

Sealing sections 5 are respectively formed around a light emitting element 2 and a zener diode 3. The sealing section 5 is formed such that the thickness of the sealing section 5 in a sideward direction of the light emitting element 2 is larger than the thickness of the sealing section 5 in an upward direction of the light emitting element 2. The sealing section 5 is formed such that a transparent medium which is a base material such as resin or glass contains a phosphor (hereinafter referred to as an “orange phosphor”) excited by blue light emitted from the light emitting element 2 to emit orange light. In the sealing section 5, particles of a phosphor (hereinafter referred to as a “red phosphor”) excited by blue light emitted from the light emitting element 2 to emit red light are dispersed as a material for adjusting chromaticity.

As the orange phosphor, any one of the following materials or a combination thereof may be used: (Ba, Sr)₂SiO₄:Eu²⁺; (Sr, Ca)₂SiO₄:Eu²⁺; (Ba, Sr, Ca)₂SiO₄:Eu²⁺; (Ba, Sr, Mg)₂SiO₄:Eu²⁺; (Sr, Eu²⁺, Yb)OSiO₂; Sr₃SiO₅:Eu²⁺; Y₃Al₅O₁₂:Ce; Y₃(Al, Ga)₅O₁₂:Ce³⁺; and Y₃(Al, Gd)₅O₁₂:Ce³⁺. The foregoing orange phosphors emit orange light with a dominant wavelength falling within a range of 555-600 nm.

In addition, for the red phosphor contained in the sealing section 5, any one of the following materials or a combination thereof may be used: CaAlSiN₃:Eu²⁺; (Sr, Ca)AlSiN₃:Eu²⁺; and Sr₂Si₅N₈:Eu²⁺. The foregoing red phosphors emit red light with a dominant wavelength falling within a range of 610-670 nm.

When the sealing sections 5 are formed by printing, a printing plate 12 having an opening corresponding to the positions of the light emitting element 2 and the zener diode 3 is arranged. Then, after the red phosphor, the amount of which is adjusted according to the amount of the orange phosphor, is added to a transparent medium such as resin or glass containing the orange phosphor, the opening of the printing plate 12 is filled with the transparent medium, and the transparent medium is cured (see FIG. 7(c)).

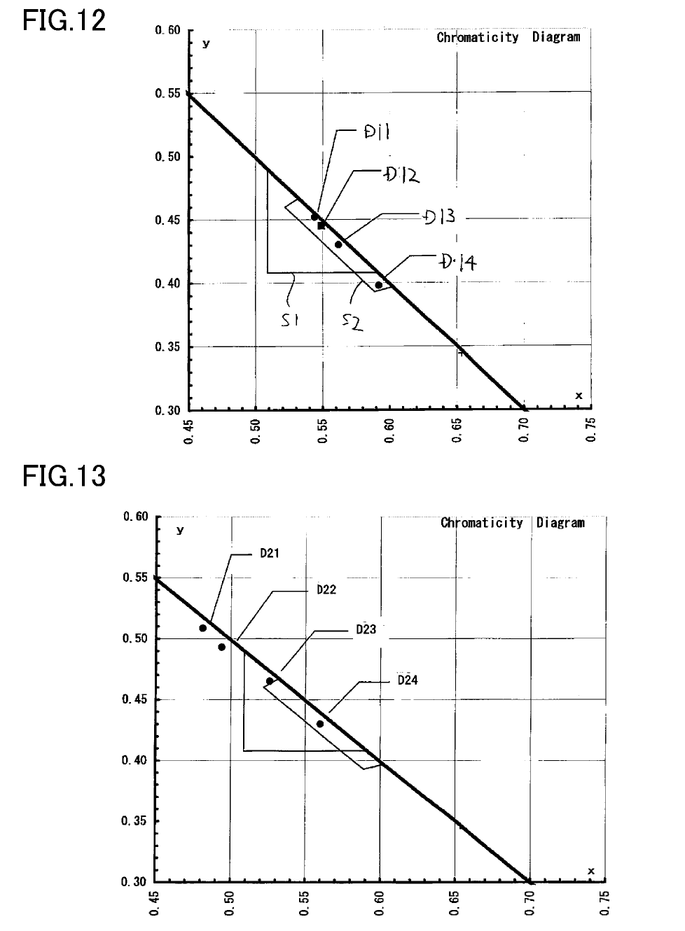

Next, a usage state of the light emitting device of the present variation and a method for adjusting a composition of phosphors will be described with reference to FIGS. 11-13. FIG. 11 is an xy chromaticity diagram illustrating the color of umber. FIGS. 12 and 13 are enlarged views of part of an xy chromaticity diagram illustrating chromaticity when a red phosphor is mixed with an orange phosphor.

Note that two types of phosphors, i.e., the orange phosphor and the red phosphor are contained in a sealing section 5. As the orange phosphor, a silicate phosphor such as a (Ba, Sr, Ca)₂SiO₄:Eu²⁺ phosphor or a (Ba, Sr, Mg)₂SiO₄:Eu²⁺ phosphor from which light having a dominant wavelength of 580-590 nm is emitted is used. In addition, as the red phosphor, a (Sr, Ca)AlSiN₃:Eu²⁺ phosphor from which light having a dominant wavelength of 640-660 nm is emitted is used. Further, a light emitting element 2 emits light having a dominant wavelength of 425-475 nm.

First, voltage is applied from a bottom electrode 42b, and then power is supplied to the light emitting element 2 through a through-hole electrode 42c and a top electrode 42a. Then, the light emitting element 2 lights up.

Blue light is emitted from the light emitting element 2 so as to not only travel directly toward outside, but also to travel after being reflected by a light reflective section 6. In the sealing section 5, both of the orange phosphor and the red phosphor contained in the sealing section 5 are excited by blue light.

Suppose that, in the xy chromaticity diagram of FIG. 11, the color of umber is represented by, e.g., values in a range (illustrated as a triangular area 51 in the figure) having x, y coordinates of (0.509, 0.408), (0.509, 0.49), and (0.591, 0.408) or values in a range (illustrated as a rectangular area S2 in the figure) having x, y coordinates of (0.603, 0.397), (0.532, 0.467), (0.522, 0.46), and (0.589, 0.393). As illustrated in FIG. 12, chromaticity of light emitted from the orange phosphor is in a position indicated by a point D11. That is, the point D11 is within the triangular area S1 and is positioned in substantially the middle of a line connecting between the color of red and the color of green. However, the point D11 is positioned closer to the color of green relative to the middle of the line in the rectangular area S2. Thus, if the color of umber to be desired is in the rectangular area S2, such a color may be displaced in a direction toward the color of green due to variation in light emitted from the light emitting element 2 and variation in light emitted from the orange phosphor. For the foregoing reason, in order to ensure a sufficient margin and obtain a color having better color rendering properties, the chromaticity of the color of umber is adjusted to be at the center of the rectangular area S2.

When the composition ratio of the orange phosphor to the red phosphor is adjusted so that the content of the red phosphor which is an adjusting material for the orange phosphor is increased as is seen from Table 2, the chromaticity of the color of light emitted from a light emitting device 1 moves to a point D12 (a composition ratio of 9:1) or a point D13 (a composition ratio of 3:1) as illustrated in FIG. 12, i.e., moves toward the color of red. The point D13 at which the composition ratio of the orange phosphor to the red phosphor is 3:1 is the closest to the center of the rectangular area S2. It can be seen that, when the composition ratio is 1:1, the chromaticity is positioned way beyond the center of the rectangular area S2, and an excessive amount of the red phosphor is added.

TABLE 2

| | | | | Position in |
|---|---|---|---|---|
| Composition Ratio | | Chromaticity | | XY Chromaticity |
| Orange Phosphor | Red Phosphor | X | Y | Diagram |
| 100 | 0 | 0.544 | 0.452 | D11 |
| 90 | 10 | 0.549 | 0.445 | D12 |
| 75 | 25 | 0.562 | 0.43 | D13 |
| 50 | 50 | 0.592 | 0.398 | D14 |

If any one of (Ba, Sr)₂SiO₄:Eu²⁺, (Sr, Ca)₂SiO₄:Eu²⁺, (Ba, Sr, Ca)₂SiO₄:Eu²⁺, or (Ba, Sr, Mg)₂SiO₄:Eu²⁺ is used for the orange phosphor, such a phosphor has high emission intensity and therefore has excellent light emitting efficiency. However, there is a problem that emission brightness is gradually reduced under high-temperature or high-humidity environment. Thus, for the orange phosphor, e.g., (Sr, Eu²⁺, Yb)OSiO₂ or Sr₃SiO₅:Eu²⁺ which has high weather resistance and from which light having a dominant wavelength of 555-580 nm is emitted is used.

As is seen from FIG. 13 and Table 3, the chromaticity of the color of light emitted from the orange phosphor is in a position indicated by a point D21, and is significantly displaced from not only the rectangular area S2 but also the triangular area S1. Thus, the composition ratio of the orange phosphor to the red phosphor is adjusted so that the content of the red phosphor which is the adjusting material for the orange phosphor is increased. At a point D23 (a composition ratio of 3:1), the chromaticity is positioned within the triangular area S1. At a point D24 (a composition ratio of 1:1), the chromaticity is not positioned within the triangular area S1, but is positioned closest to the center of the rectangular area S2.

TABLE 3

| | | | | Position in |
|---|---|---|---|---|
| Composition Ratio | | Chromaticity | | XY Chromaticity |
| Orange Phosphor | Red Phosphor | X | Y | Diagram |
| 100 | 0 | 0.481 | 0.509 | D21 |
| 90 | 10 | 0.494 | 0.493 | D22 |
| 75 | 25 | 0.526 | 0.465 | D23 |
| 50 | 50 | 0.592 | 0.398 | D24 |

As described above, in the light emitting device 1 of the present variation, since the red phosphor is contained in the sealing section 5 as the adjusting material, fine adjustment of the chromaticity is allowed, which cannot be performed in a case where only the orange phosphor is contained in the sealing section 5.

Note that, in the present variation, a case where only a single type of the orange phosphor and a single type of the red phosphor are contained in the sealing section 5 has been described. However, the color of umber can be similarly adjusted by combining two or more types of the orange phosphors and/or two or more types of the red phosphors.

Both of the orange phosphor and the red phosphor are excited by blue light emitted from the light emitting element 2 to emit light. However, the light emitting element may emit ultraviolet light. In such a case, the red phosphor may be excited by ultraviolet light to emit light. In addition, a phosphor for emitting blue light by ultraviolet light may be contained in the sealing section 5, or may be contained in a sealing layer provided in the sealing section 5.

In the present variation, the orange phosphor and the red phosphor are contained in the same sealing section 5. However, the orange phosphor and the red phosphor may be contained in different sealing layers, and the sealing section may include a plurality of layers. In such a case, it is preferable that the wavelength of light emitted from the phosphor is gradually shortened from the light emitting element 2 toward outside. That is, it is preferable that the red phosphor is positioned on an inner side relative to the orange phosphor.

### Second Embodiment

A second embodiment relates to a light emitting device in which excellent spectral properties of a color filter can be realized by reducing an overlap between an emission color corresponding to a dominant wavelength and each of emission colors corresponding to adjacent dominant wavelengths, and to a color liquid crystal apparatus using the light emitting device.

First, the related art of the present embodiment will be described.

In a light emitting device described in Patent Document 3, a phosphor contained in an upper wavelength conversion material layer converts light into green light having a shorter wavelength than that of red light into which the light is converted by a phosphor contained in a lower wavelength conversion material layer. Thus, the phosphor for emitting green light can emit light without providing influence on red light emitted from the lower wavelength conversion material layer and losing green light emission.

However, blue light emitted from a light emitting element, red light into which the blue light is converted in the lower wavelength conversion material layer, and green light into which the blue light is converted in the upper wavelength conversion material layer have properties that intensity is attenuated, like extension of a mountain at the foot thereof, in a short-wavelength direction and a long-wavelength direction, supposing that a dominant wavelength is a peak wavelength. Thus, e.g., the dominant wavelength of blue light emitted from the light emitting element and the dominant wavelength of green light emitted from the upper wavelength conversion material layer are adjacent to each other, and the blue light and the green light partially overlaps with each other corresponding to an intermediate wavelength therebetween. As a result, there is a possibility that a disadvantage that emission intensity is increased is caused.

Such a disadvantage may be caused in a case where the light emitting device described in Patent Document 3 is used as a light source of a backlight of the color liquid crystal apparatus used for, e.g., a flat-screen television and including the color filter. It is ideal that only light having a single wavelength transmits through a color filter. However, blue light emitted from the light emitting element, red light into which the blue light is converted in the lower wavelength conversion material layer, and green light into which the blue light is converted in the upper wavelength conversion material layer have the transmission properties that the intensity is attenuated, like extension of a mountain at the foot thereof, in the short-wavelength direction and the long-wavelength direction, supposing that the dominant wavelength is the peak wavelength. Thus, not only green light emitted from the upper wavelength conversion material layer but also a longer wavelength part of blue light emitted from the light emitting element transmit through a green filter. When light having strength in a state in which a shorter wavelength part of green light and the longer wavelength part of blue light mixed together transmits through the green filter, there is a possibility that a balance with other colors is upset and therefore an image has a poor color tone.

That is, in the light emitting device described in Patent Document 3, a problem may be caused, in which the color filter through which light having a predetermined color transmits is adversely influenced by light having an emission color corresponding to a wavelength shorter than that of light having the predetermined color.

The inventors of the present invention have arrived at realizing a color filter having excellent spectral properties by reducing an overlap between an emission color corresponding to a dominant wavelength and each of emission colors having adjacent dominant wavelengths, and this leads to the present embodiment.

A preferable embodiment is directed to a light emitting device in which a light emitting element is mounted on a base and two or more sealing sections are successively provided so as to cover the light emitting element. In a first sealing section of the two or more sealing sections, a phosphor excited by inner light emitted from an inner side relative to the first sealing section and emitting light having a dominant wavelength adjacent to the wavelength of the inner light is contained. In a second sealing section positioned on an outer side relative to the first sealing section, a phosphor emitting light having a wavelength longer than that of light emitted from the phosphor contained in the first sealing section is contained, and the phosphor contained in the second sealing section is excited by the inner light and light having a wavelength corresponding to an overlap between a longer wavelength part of inner light and a shorter wavelength part of light emitted from the first sealing section.

According to the foregoing embodiment, since the phosphor of the second sealing section positioned on the outer side relative to the first sealing section is excited by the shorter wavelength part of light emitted from the phosphor of the first sealing section, the shorter wavelength part of light emitted from the phosphor of the first sealing section is lost, and such light is attenuated. Thus, even if emission wavelength properties show that the shorter wavelength part of light emitted from the first sealing section overlaps with the longer wavelength part, which is adjacent to the dominant wavelength of light emitting from the first sealing section, of inner light emitted from the inner side relative to the first sealing section, the overlap can be reduced.

A more preferable embodiment is directed to a light emitting device in which a light emitting element emits blue light, a first sealing section receives the blue light from the light emitting element to emit green light, and a second sealing section receives the blue light and the green light to emit red light.

According to the foregoing embodiment, since the foregoing configuration allows a shorter wavelength part of green light emitted from the first sealing section to excite a phosphor for emitting red light from the second sealing section, the shorter wavelength part of green light is lost, and such green light is attenuated. Thus, although emission wavelength properties show that the shorter wavelength part of green light emitted from the first sealing section and a longer wavelength part of light emitted from the light emitting element overlap with each other, the overlap can be reduced.

A color liquid crystal panel may include a backlight using the light emitting device of the present embodiment as a light source, and a primary color filter having the backlight on a back surface thereof.

In the color liquid crystal panel, the light emitting device of the foregoing embodiment is used as the light source of the backlight. Thus, although the emission wavelength properties show that the shorter wavelength part of green light emitted from the first sealing section and the longer wavelength part of light emitted from the light emitting element overlap with each other, the overlap can be reduced.

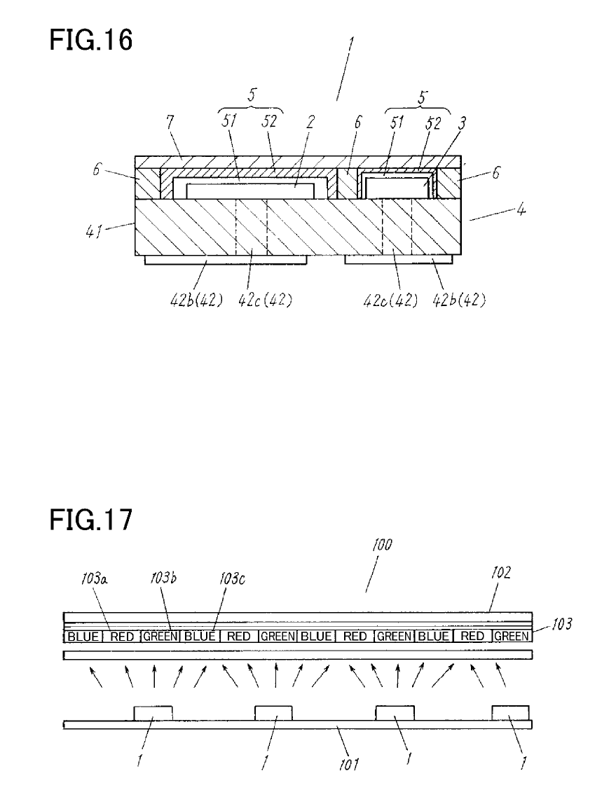

The light emitting device of the present embodiment will be described with reference to drawings. FIG. 15 is a plan view illustrating the light emitting device of the present embodiment. FIG. 16 is a cross-sectional view of the light emitting device illustrated in FIG. 15 along an A-A line. FIG. 3 is the bottom view of the light emitting device illustrated in FIG. 15. FIG. 4 is the cross-sectional view illustrating the light emitting element. FIG. 5 is the plan view illustrating the light emitting element. FIG. 6 is the circuit diagram illustrating the connection between the light emitting element and the zener diode.

As illustrated in FIGS. 3, 15, and 16, a light emitting device 1 is a light emitting diode (LED) emitting white light and including a light emitting element 2, a zener diode 3, a wiring substrate 4, sealing sections 5, a light reflective section 6, and a light diffusion section 7. The light emitting device 1 is formed in a shape of a rectangular of about 2 mm×1.6 mm so as to have a thickness of about 0.75 mm.

The light emitting element 2 is a flip-chip light emitting diode including a substrate 21, an n-type layer 22, an active layer 23, a p-type layer 24, an n-side electrode 25, and a p-side electrode 26, and emitting blue light having a dominant wavelength of 425-475 nm.

The substrate 21 functions to hold a semiconductor layer including the n-type layer 22, the active layer 23, and the p-type layer 24. Sapphire having insulating properties may be used as the material of the substrate 21. However, since gallium nitride (GaN) is a base material of a light emitting part considering light emitting efficiency, GaN, SiC, AlGaN, or AlN having the same refractive index as that of a light emitting layer is preferably used in order to reduce light reflection at an interface between the n-type layer 22 and the substrate 21.

The n-type layer 22, the active layer 23, and the p-type layer 24 which are light emitting layers are stacked in this order on the substrate 21. It is preferable that the material of the light emitting layers is a gallium nitride compound. Specifically, the n-type layer 22, the active layer 23, and the p-type layer 24 are made of GaN, InGaN, and GaN, respectively. Note that AlGaN or InGaN may be used for the n-type layer 22 or the p-type layer 24. A buffer layer made of GaN or InGaN may be formed between the n-type layer 22 and the substrate 21. The active layer 23 may have, e.g., a multi-layer structure (quantum well structure) in which an InGaN layer and a GaN layer are alternately stacked.

Part of the n-type layer 22 is exposed by removing part of the n-type layer 22, part of the active layer 23, and part of the p-type layer 24 which are stacked on the substrate 21, and the n-side electrode 25 is provided on the exposed part of the n-type layer 22. Note that, if a substrate is a conductive member, part of the substrate may be exposed and the n-side electrode 25 may be directly provided on the exposed part of the substrate.

The p-side electrode 26 is provided on the p-type layer 24. That is, since part of the n-type layer 22 is exposed by removing part of the active layer 23 and part of the p-type layer 24, the light emitting layers, the p-side electrode 26, and the n-side electrode 25 are provided on the same side relative to the substrate 21.

The p-side electrode 26 is an electrode made of, e.g., Ag, Al, or Rh having high reflectivity in order to reflect light emitted from the light emitting layers toward the substrate 21.

In order to reduce contact resistance between the p-type layer 24 and the p-side electrode 26, an electrode layer made of, e.g., Pt, Ni, Co, or ITO is preferably formed between the p-type layer 24 and the p-side electrode 26. The n-side electrode 25 may be made of, e.g., Al or Ti. In order to increase the strength of bonding with other elements or wires, Au or Al is preferably used on surfaces of the p-side electrode 26 and the n-side electrode 25. Such electrodes may be formed by, e.g., vacuum deposition or sputtering.

The entire area of the light emitting element 2 may be large in order to increase a light amount, and the length of one side of the light emitting element 2 is preferably equal to or greater than 600 μm.

Note that the flip-chip light emitting element has been described in detail as the light emitting element 2, but other types of light emitting elements may be used.

In the present embodiment, the zener diode 3 has been described as the protective element, but the protective element may be a diode, a capacitor, a resistor, or a varistor.

The wiring substrate 4 is a printed circuit board functioning as a base, i.e., an insulating substrate 41 in which a wiring pattern 42 is formed. The wiring pattern 42 includes top electrodes 42a provided on a mounting surface of the wiring substrate 4, bottom electrodes 42b provided on a surface of the wiring substrate 4 opposite to the mounting surface of the wiring substrate 4, and through-hole electrodes 42c each connecting the top electrode 42a and the bottom electrode 42b together. The insulating substrate 41 may be a glass epoxy resin substrate, a BT resin (thermosetting resin such as bismaleimide triazine resin) substrate, or a ceramic (alumina or aluminum nitride) substrate.

The sealing sections 5 are formed around the light emitting element 2 and the zener diode 3. The sealing section 5 is formed by dispersing inorganic or organic phosphor particles in a transparent medium which is a base material such as resin or glass. The sealing section 5 includes two sealing sections successively covering the light emitting element. The two sealing sections are a first sealing section 51 and a second sealing section 52 positioned on an outer side relative to the first sealing section 51.

In the first sealing section 51, a phosphor excited by blue light emitted from the light emitting element 2 to emit green light having a dominant wavelength which is adjacent to the dominant wavelength of the blue light and which is 510-550 nm, preferably 525-530 nm, is contained. For the phosphor, e.g., the following materials can be used: (Ba, Sr)₂SiO₄:Eu²⁺; (Sr, Ca)₂SiO₄:Eu²⁺; (Ba, Sr, Ca)₂SiO₄:Eu²⁺; (Ba, Sr, Mg)₂SiO₄:Eu²⁺; and CaSc₂O₄:Ce.

In the second sealing section 52, a phosphor excited by light emitted from the light emitting element 2 and green light emitted from the first sealing section 51 to emit red light having a dominant wavelength of equal to or greater than 610 nm and equal to or less than 670 nm, preferably equal to or greater than 640 nm and equal to or less than 660 nm, is contained. For the phosphor, e.g., the following materials can be used: CaAlSiN₃:Eu²⁺; (Sr, Ca)AlSiN₃:Eu²⁺; and Sr₂Si₅N₃: Eu²⁺.

As the transparent medium, e.g., resin containing silicone resin, epoxy resin, and fluorine resin as main components or a glass material produced by a sol-gel method may be used. Some glass materials have a curing reaction temperature of about 200 degrees Celsius, and the glass material is a preferable material considering heat resistance of materials used for bumps and electrode sections.

The light reflective section 6 is formed by dispersing particles for reflecting light emitted from the light emitting element 2 in a transparent medium which is a base material made of resin such as epoxy resin, acrylic resin, polyimide resin, urea resin, silicone resin, and fluorine resin or made of glass. The light reflective section 6 is formed so as to surround part of the sealing sections 5 respectively sealing the light emitting element 2 and the zener diode 3, other than top surfaces of the sealing sections 5.

The light reflective section 6 can be formed by curing liquid resin containing titanium oxide particles for reflecting light as a reflective material and a dispersant. Since the light reflective section 6 is formed by curing the liquid resin containing the titanium oxide powder and the dispersant, insulating properties can be maintained in the light reflection section 6, and a reflex function can be provided to the light reflection section 6. When the light reflective section 6 is formed, a thixotropy imparting agent may be added to the liquid resin for the purpose of enhancing liquidity. As the thixotropy imparting agent, e.g., fine silica powder may be used.

Note that, in the present embodiment, titanium oxide is used as the reflective material, but, e.g., aluminum oxide, silica dioxide, and boron nitride may be used as the reflective material. That is, as long as a material is a metal oxide having the insulating properties and the reflex function, such a material may be used as the reflective material.

In the present embodiment, since the light reflective section 6 contains titanium oxide, the light reflective section 6 has both of insulating properties and light reflectivity. However, a reflecting section may be formed by adding SiO₂ to resin or mixing other metal oxide with resin.

The light diffusion section 7 is formed by dispersing particles for diffusing light emitted from the light emitting element 2 in a transparent medium which is a base material made of resin such as epoxy resin, acrylic resin, polyimide resin, urea resin, silicone resin, and fluorine resin or made of glass. The light diffusion section 7 is formed across the entirety of top surfaces of the sealing sections 5 and the light reflective section 6. SiO₂ particles may be used as the particles for diffusing light emitted from the light emitting element 2.

Next, a color liquid crystal apparatus including light emitting devices 1 as a light source of a backlight will be described with reference to FIG. 17.

A color liquid crystal apparatus 100 is a liquid crystal display apparatus used for, e.g., a television and a car navigation system, in which the light emitting devices 1 are arranged in a matrix on a wiring substrate 101 as the light source of the backlight and the wiring substrate 101 is arranged so as to face a back surface of a liquid crystal panel 102. A color filter 103 of three primary colors of red, green, and blue is arranged in a dot-matrix corresponding to liquid crystal cells (not shown in the figure) on the liquid crystal panel 102. A red filter 103a of the color filter 103 has the maximum transmission properties at 600-670 nm. A green filter 103b has the maximum transmission properties at 510-550 nm. A blue filter 103c has the maximum transmission properties at 425-475 nm. In the present embodiment, a light guide plate is not provided as the backlight, but the liquid crystal panel 102 may be irradiated with light emitted from the light emitting devices 1 through the light guide plate.

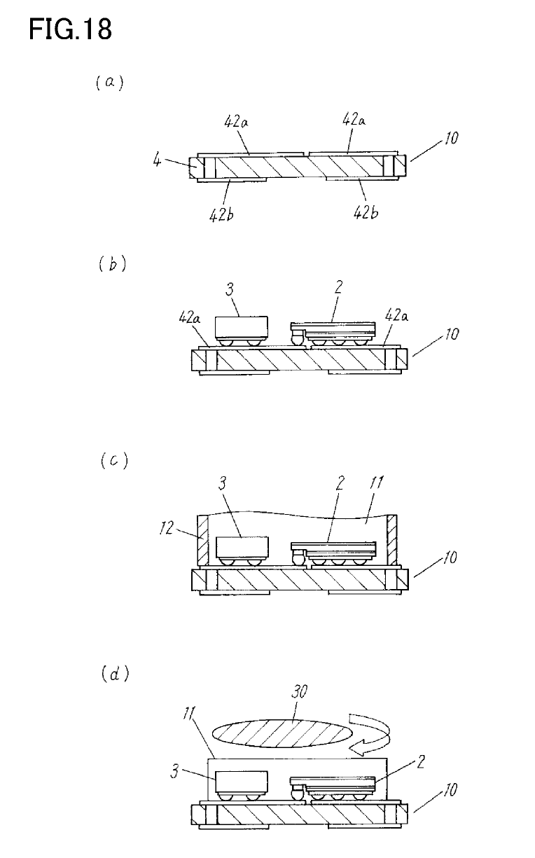

A method for manufacturing the light emitting device of the present embodiment configured as described above will be described with reference to FIGS. 18-21. FIGS. 18-20 are views illustrating steps for manufacturing the light emitting device illustrated in FIG. 15. Note that, in FIGS. 18(a)-20(d), only a single light emitting device is illustrated.

A base material 10 on which wiring substrates 4 are continuously arranged in a matrix is prepared in order to produce a plurality of light emitting devices 1 (see FIG. 18(a)). A light emitting element 2 and a zener diode 3 are mounted on top electrodes 42a formed on the base material 10, respectively (see FIG. 18(b)).

Next, a first phosphor layer 11 to be formed into first sealing sections 51 for respectively sealing the light emitting element 2 and the zener diode 3 is formed. Printing allows easy formation of the first sealing sections 51 in a short time. When the first sealing sections 51 are formed by the printing, a printing plate 12 having an opening corresponding to the positions of the light emitting element 2 and the zener diode 3 is arranged. Then, the opening of the printing plate 12 is filled with a transparent medium containing a phosphor for emitting green light and made of resin or glass, and the transparent medium is cured (see FIG. 18(c)).

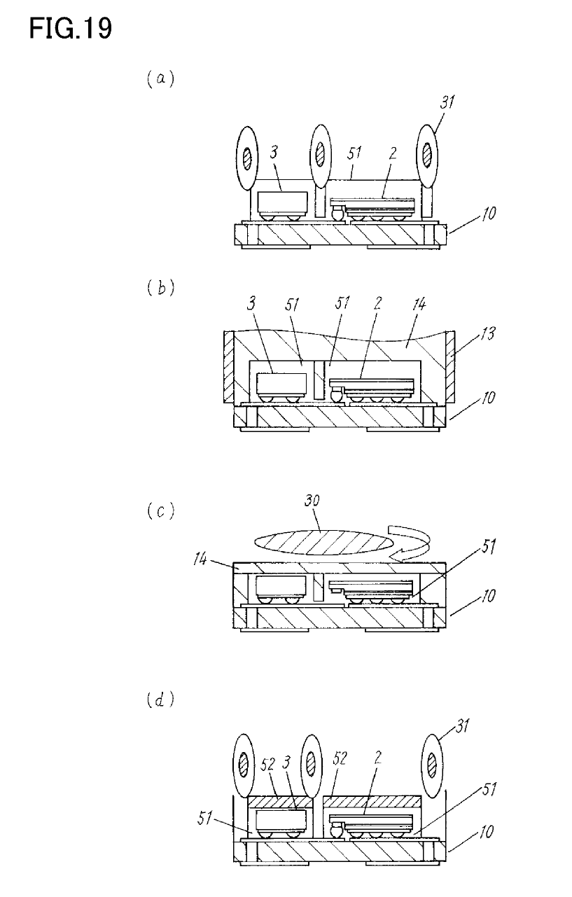

When the first phosphor layer 11 is cured, a top surface of the first phosphor layer 11 is polished into a smooth surface by a polishing machine 30 (see FIG. 18(d)). Next, the first phosphor layer 11 is cut, and then second sealing sections 52 are formed. Positions where the first phosphor layer 11 is cut are a position of the first phosphor layer 11 between the light emitting element 2 and the zener diode 3, and positions of end portions of the first phosphor layer 11 formed by the printing plate 12 (see FIG. 18(c)), i.e., a position of a side portion of the first phosphor layer 11 on a side close to the light emitting element 2 and a position of a side portion of the first phosphor layer 11 on a side close to the zener diode 3. In such positions, the first phosphor layer 11 is cut by a cutting machine 31 such that the cutting machine 31 reaches a mounting surface of the wiring substrate 4 from the top surface of the first phosphor layer 11 (see FIG. 19(a)). A groove is formed between the light emitting element 2 and the zener diode 3 by cutting the first phosphor layer 11, and both side surfaces of the first phosphor layer 11 are smoothed. In such a manner, the first phosphor layer 11 is formed into the first sealing sections 51.

Next, a printing plate 13 is arranged so as to surround the entirety of the first sealing sections 51. An opening of the printing plate 13 is filled with a transparent medium containing a phosphor for emitting red light and made of resin or glass, and the transparent medium is cured. In such a manner, a second phosphor layer 14 is formed (see FIG. 19(b)). When the second phosphor layer 14 is cured, a top surface of the second phosphor layer 14 is polished into a smooth surface by the polishing machine 30 (see FIG. 19 (c)).

Next, the second phosphor layer 14 is cut, and then a light reflective section 6 is formed. Positions where the second phosphor layer 14 is cut are a position of the second phosphor layer 14 between the light emitting element 2 and the zener diode 3, and positions of end portions of the second phosphor layer 14 formed by the printing plate 13 (see FIG. 19(b)), i.e., a position of a side portion of the second phosphor layer 14 on a side close to the light emitting element 2 and a position of a side portion of the second phosphor layer 14 on a side close to the zener diode 3. In such positions, the second phosphor layer 14 is cut by the cutting machine 31 such that the cutting machine 31 reaches the mounting surface of the wiring substrate 4 from the top surface of the second phosphor layer 14. A groove is formed between the light emitting element 2 and the zener diode 3 by cutting the second phosphor layer 14, and both side surfaces of the second phosphor layer 14 are smoothed. In such a manner, the second phosphor layer 14 is formed into the second sealing sections 52.

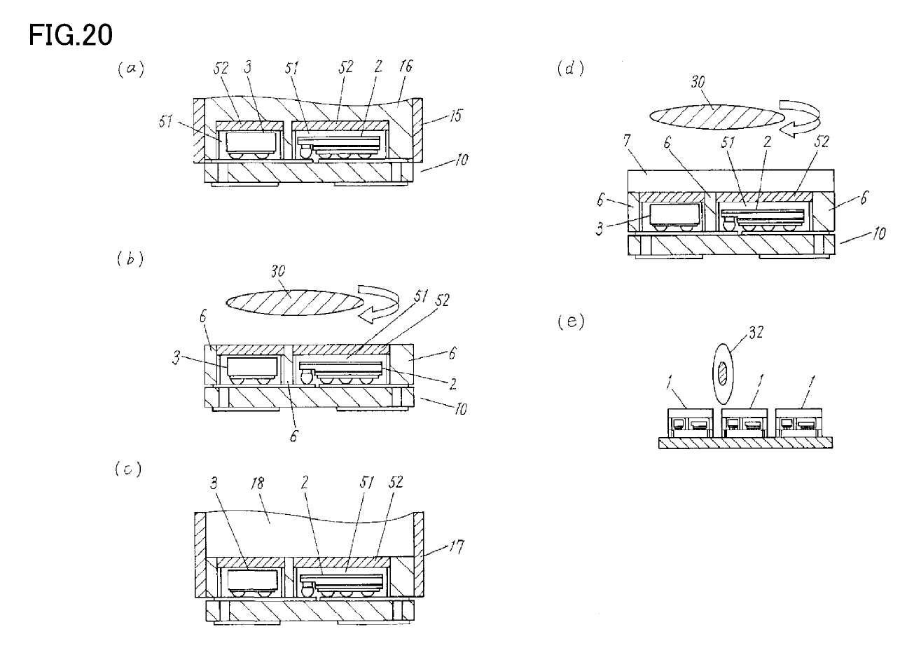

Next, a printing plate 15 is arranged so as to surround the entirety of the second sealing sections 52. An opening of the printing plate 15 is filled with resin or glass in which particles for reflecting light emitted from the light emitting element 2 are dispersed, and the resin or glass is cured. In such a manner, a reflective layer 16 is formed (see FIG. 20(a)).

Then, the entirety of the reflective layer 16 is polished by the polishing machine 30 until the second sealing sections 52 are exposed. Since part of the reflective layer 16 is polished until top surfaces of the second sealing sections 52 are exposed, the remaining part of the reflective layer 16 serves as the light reflective section 6 (see FIG. 20(b)). Since the groove is formed between the light emitting element 2 and the zener diode 3 in the second phosphor layer 14 in advance, the light reflective section 6 can be formed so as to surround the light emitting element 2. Thus, light emitted from the light emitting element 2 toward side can be reflected by the light reflective section 6 without being blocked by the zener diode 3.

Next, a printing plate 17 having an opening corresponding to the entirety of the polished second sealing sections 52 and the polished light reflective section 6 is arranged, and the opening of the printing plate 17 is filled with resin or glass in which particles for reflecting light emitted from the light emitting element 2 are dispersed. In such a manner, a light diffusion layer 18 is formed (see FIG. 20(c)).

Next, a top surface of the light diffusion layer 18 is polished into a smooth surface by the polishing machine 30, thereby forming the light diffusion layer 18 into a light diffusion section 7 (see FIG. 20(d)). The base material 10 is cut in longitudinal and lateral directions into pieces by a dicer 32 (see FIG. 20(e)). In such a manner, the light emitting device 1 illustrated in FIGS. 3, 15, and 16 can be produced.

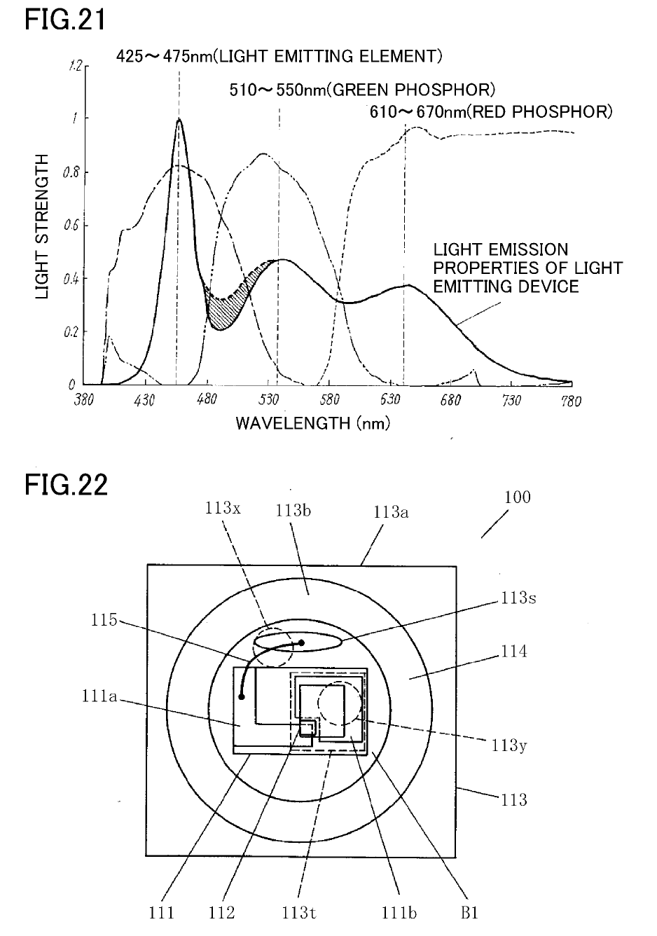

Next, a usage state of the light emitting device of the present embodiment will be described with reference to FIGS. 3, 15, 16, and 21. FIG. 21 is a graph illustrating a relationship between an emission wavelength of the light emitting device illustrated in FIG. 15 and a transmission wavelength of the color filter.

First, voltage is applied from the bottom electrode 42b, and then power is supplied to the light emitting element 2 through the through-hole electrode 42c and the top electrode 42a. Then, the light emitting element 2 lights up.

Blue light is emitted from the light emitting element 2 so as to not only travel directly from the first sealing section 51 toward the second sealing section 52, but also to travel after being reflected by the light reflective section 6. In the first sealing section 51, the phosphor contained in the first sealing section 51 is excited by blue light, i.e., inner light, emitted from the light emitting element 2, and such blue light is converted into green light by wavelength conversion. The green light emitted from the phosphor of the first sealing section 51 travels toward the second sealing section 52 together with the blue light emitted from the light emitting element 2.

In the second sealing section 52, the phosphor contained in the second sealing section 52 is excited not only by blue light emitted from the light emitting element 2, but also by a shorter wavelength part of green light emitted from the first sealing section 51 and having a wavelength of 470-530 nm. Then, red light is emitted.

That is, since the shorter wavelength part of green light is used for the excitation of the phosphor for emitting red light, the shorter wavelength part of green light emitted from the phosphor of the first sealing section 51 is lost, and such green light is attenuated. Thus, although emission wavelength properties illustrated in FIG. 11 show that the shorter wavelength part of green light emitted from the first sealing section 51 and a longer wavelength part of light emitted from an inner side relative to the first sealing section, i.e., a longer wavelength part of blue light emitted from the light emitting element 2 overlap with each other, the overlap can be reduced (a hatched part in FIG. 21 indicates a range where the shorter wavelength part of green light and the longer wavelength part of blue light no longer overlap with each other).

The overlap of the shorter wavelength part of green light and the longer wavelength part of blue light is reduced, thereby obtaining green light having properties that a predetermined wavelength range is narrower. Thus, in the color liquid crystal apparatus 100 including the light emitting devices 1 as the light source of the backlight as illustrated in FIG. 17, the wavelength range of light transmitting through the green filter 103b can be narrower. As a result, spectral properties can be improved, and an image can be displayed with a good color tone and good contrast.

In the present embodiment, the emission color of white is obtained by the light emitting element 2 for emitting blue light, the first sealing section 51 containing the phosphor for emitting green light, and the second sealing section 52 positioned on an outer side relative to the first sealing section 51 and containing the phosphor for emitting red light as illustrated in FIG. 15. However, other combination of the emission color of the light emitting element and the emission color of the phosphor may be applied. For example, the emission color of white may be obtained by the following configuration: the light emitting element emits ultraviolet light; the first sealing section contains a phosphor for emitting green light by ultraviolet light; the second sealing section contains a phosphor for emitting red light by ultraviolet light; a third sealing section is further provided on an inner side relative to the first sealing section; and the third sealing section contains a phosphor for emitting blue light by ultraviolet light which is inner light.

That is, when two or more sealing sections are successively provided so as to cover the light emitting element, an outer sealing section may contain a phosphor for emitting light having an emission wavelength longer than that of light emitted from a phosphor contained in an inner sealing section.

Note that, in the present embodiment, the liquid crystal display apparatus has been described as the color liquid crystal apparatus, but the color liquid crystal apparatus may be, e.g., a projection apparatus such as a liquid crystal projector.

### Third Embodiment

A third embodiment relates to a light emitting device which allows higher brightness by sealing a light emitting element by a sealant having high heat resistance.

First, the related art of the present embodiment will be described.

As the sealant for sealing the light emitting element, epoxy resin or silicone resin is used. Although the epoxy resin has excellent properties in ease of handling, moldability, and a cost, there are disadvantages such as yellowing due to ultraviolet light or blue light and a low heat resistance temperature. The silicone resin is more resistant to ultraviolet light or blue light as compared to the epoxy resin, and has excellent heat resistance. Thus, the silicone resin is a material suitable as a sealant of a light emitting element for emitting ultraviolet light or blue light in a case where the emission color of light emitted from such a light emitting element and the emission color of light emitted from a phosphor are mixed together to obtain the emission color of white.

A light emitting device using the silicone resin as a sealant of a light emitting element is described in, e.g., Patent Document 4.

However, at equal to or higher than 150° C., a change in hardness of the silicone resin is occurred, resulting in problems such as cracking and deformation. With development of a high-brightness light emitting element, the temperature of the light emitting element sometimes exceeds 150° C. due to large current application. When the silicone resin is exposed to a high temperature, the silicone resin is oxidized, resulting in occurrence of formaldehyde or low-molecular siloxane. Thus, the transmittance of the silicone resin is reduced, and transparency of the silicone resin is lost.

Since, as compared to a fluorescent lamp or a light bulb, the light emitting device has a longer life and requires less power, it is expected that a demand for the light emitting device as a light source for a light apparatus or a display apparatus will be increased and that a high-brightness light emitting device will be further developed.

The inventors of the present invention have arrived at realizing a high-brightness light emitting device by sealing a light emitting element by using a sealant having high heat resistance, and this leads to the present embodiment.

A preferable embodiment is directed to a light emitting device including a light emitting element sealed by a sealant, in which the sealant is resin represented by a composition formula of —(RnSiO_{(4-n)/2)}m- (where “R” is an alkyl group, “n” is 1, and “m” is an integer).

According to the foregoing embodiment, the resin represented by the composition formula of —(RnSiO_{(4-n)/2)}m- (where “R” is an alkyl group, “n” is 1, and “m” is an integer) has high heat resistance to about 300° C. Thus, by using such resin as the sealant, reduction in transmittance due to oxidization under high temperature and occurrence of yellowing or blacking due to deterioration can be prevented in the sealing section even when large current is applied to the high-brightness light emitting element. As a result, the light emitting element can continuously light up.

Another preferable embodiment is directed to a method for manufacturing a light emitting device including a light emitting element sealed by a sealant. The manufacturing method includes the steps of: mounting the light emitting element on a base; forming a sealing layer for sealing the light emitting element after the sealant formed by dissolving resin represented by a composition formula of —(RnSiO_{(4-n)/2)}m- (where “R” is an alkyl group, “n” is 1, and “m” is an integer) in a solvent is applied to the light emitting element and is cured; and forming at least one resin layer after a resin material is applied to the sealing layer and is cured.

According to the foregoing embodiment, when the sealant formed by dissolving the resin in the solvent is cured, the solvent is volatilized and a great change in volume of the sealant is occurred. However, Since at least one resin layer is formed after the resin material is dropped onto the sealing layer and is cured, the lost volume can be compensated.

In a more preferable embodiment, a sealing layer is, in the step of forming a sealing layer, formed by a sealant containing a phosphor excited by light emitted from a light emitting element to emit light.

According to the foregoing embodiment, the phosphor is contained in the sealing layer. Thus, when a change in volume of the sealing layer is occurred, i.e., the volume of the sealing layer is reduced, in association with the curing of the sealing layer, dispersed phosphor particles can be gathered close to the light emitting element in association with the reduction of the volume of the sealing layer. As a result, since a phosphor layer can be formed such that the phosphor particles are gathered around the light emitting element, light emitted from the light emitting element can efficiently reach the phosphor.

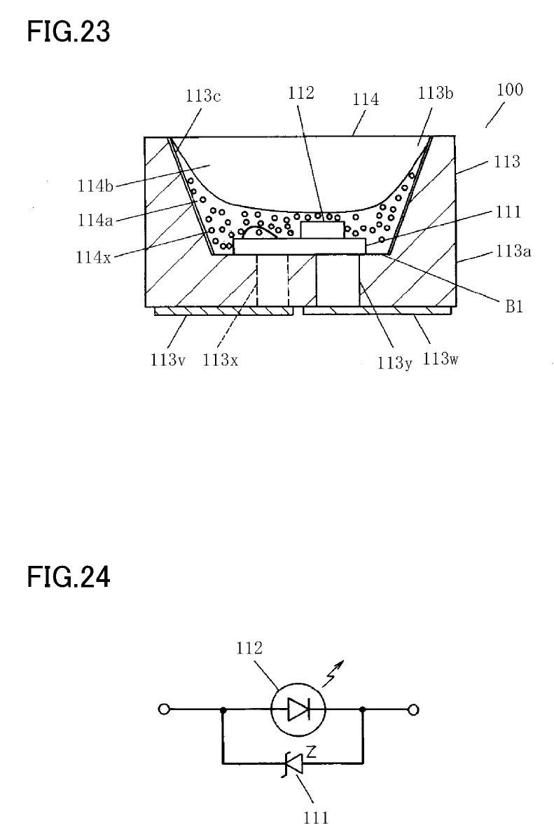

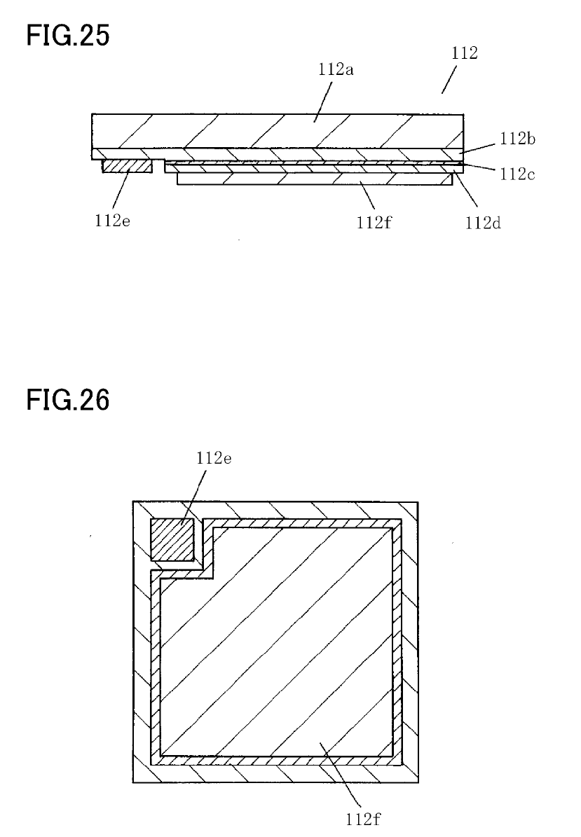

Next, the light emitting device of the present embodiment will be described with reference to drawings. FIG. 22 is a plan view of the light emitting device of the present embodiment. FIG. 23 is a cross-sectional view of the light emitting device illustrated in FIG. 22. FIG. 24 is a circuit diagram of the light emitting device illustrated in FIG. 22. FIG. 25 is a cross-sectional view of a light emitting element used for the light emitting device illustrated in FIG. 22. FIG. 26 is a plan view of the light emitting element illustrated in FIG. 25.

As illustrated in FIGS. 22 and 23, a light emitting device 100 includes a protective element 111, a light emitting element 112, a base 113, and a sealing resin section 114.

The protective element 111 is a zener diode on which the light emitting element 112 is mounted so as to be in conduction with an upper cathode electrode 111a and an upper anode electrode 111b, and in which a p-type semiconductor region is provided in part of an n-type silicon substrate so that excessive voltage is not applied to the light emitting element 112. The circuit diagram in a state in which the light emitting element 112 is mounted on the protective element 111 is illustrated in FIG. 24. In the present embodiment, a zener diode Z has been described as the protective element 111, but the protective element 111 may be a diode, a capacitor, a resistor, a varistor, or a printed circuit board in which a wiring pattern is formed in an insulating substrate. Power is supplied to the protective element 111 through a bottom electrode (not shown in the figure) and a wire 115.

As illustrated in FIGS. 25 and 26, the light emitting element 112 is a flip-chip light emitting diode for emitting blue light, and includes a substrate 112a, an n-type layer 112b, an active layer 112c, a p-type layer 112d, an n-side electrode 112e, and a p-side electrode 112f.

The substrate 112a functions to hold a semiconductor layer including the n-type layer 112b, the active layer 112c, and the p-type layer 112d. Sapphire having insulating properties may be used as the material of the substrate 112a. However, since gallium nitride (GaN) is a base material of a light emitting part considering light emitting efficiency, GaN, SiC, AlGaN, or AlN having the same refractive index as that of a light emitting layer is preferably used in order to reduce light reflection at an interface between the n-type layer 112b and the substrate 112a.

The n-type layer 112b, the active layer 112c, and the p-type layer 112d which are light emitting layers are stacked in this order on the substrate 112a. It is preferable that the material of the light emitting layers is a gallium nitride compound. Specifically, the n-type layer 112b, the active layer 112c, and the p-type layer 112d are made of GaN, InGaN, and GaN, respectively. Note that AlGaN or InGaN may be used for the n-type layer 112b or the p-type layer 112d. A buffer layer made of GaN or InGaN may be formed between the n-type layer 112b and the substrate 112a. The active layer 112c may have, e.g., a multi-layer structure (quantum well structure) in which an InGaN layer and a GaN layer are alternately stacked.

Part of the n-type layer 112b is exposed by removing part of the n-type layer 112b, part of the active layer 112c, and part of the p-type layer 112d which are stacked on the substrate 112a, and the n-side electrode 112e is provided on the exposed part of the n-type layer 112b. Note that, if a substrate is a conductive member, part of the substrate may be exposed and an n-side electrode may be directly provided on the exposed part of the substrate.

The p-side electrode 112f is provided on the p-type layer 112d. That is, since part of the n-type layer 112b is exposed by removing part of the active layer 112c and part of the p-type layer 112d, the light emitting layers, the p-side electrode 112f, and the n-side electrode 112e are provided on the same side relative to the substrate 112a.

The p-side electrode 112f is an electrode made of, e.g., Ag, Al, or Rh having high reflectivity in order to reflect light emitted from the light emitting layers toward the substrate 112a.

In order to reduce contact resistance between the p-type layer 112d and the p-side electrode 112f, an electrode layer made of, e.g., Pt, Ni, Co, or ITO is preferably formed between the p-type layer 112d and the p-side electrode 112f. The n-side electrode 112e may be made of, e.g., Al or Ti. In order to increase the strength of bonding with other elements or wires, Au or Al is preferably used on surfaces of the p-side electrode 112f and the n-side electrode 112e. Such electrodes may be formed by, e.g., vacuum deposition or sputtering.

The entire area of the light emitting element 112 may be large in order to increase a light amount, and the length of one side of the light emitting element 112 is preferably equal to or greater than 600 μm.

Note that the flip-chip light emitting element has been described in detail as the light emitting element 112, but other types of light emitting elements may be used.

As illustrated in FIGS. 22 and 23, a recess 113b is provided in a rectangular parallelepiped base body 113a of the base 113, and the protective element 111 and the light emitting element 112 are mounted on the bottom of the recess 113b. A bottom cathode electrode 113v and a bottom anode electrode 113w which are made of a metal film are provided on a bottom surface of the base body 113a of the base 113. The bottom cathode electrode 113v is conductively connected to a wiring pattern 113s formed in a mounting surface B1, on which the protective element 111 is mounted, of the base body 113a through a through-hole wire 113x. In addition, the bottom anode electrode 113w is conductively connected to a die-bonding pattern 113t formed in the mounting surface B1 connected to the protective element 111, through a through-hole wire 113y.

An inner circumferential wall surface of the recess 113b of the base body 113a is a reflective surface 113c which defines an opening with an opening area gradually increased in a traveling direction of light emitted from the light emitting element 112. The reflective surface 113c of the base 113 will be described below in detail.

The base body 113a may be made of, e.g., amodel (registered trademark) which is polyphthalamide resin. If the base body 113a is made of polyphthalamide resin, the reflective surface 113c which is the inner circumferential wall surface of the recess 113b may be a surface to which a silicon dioxide film or a double film made of a silicon dioxide film formed on an aluminum film or a silver film is adhered.

Other than polyphthalamide resin, the base body 113a may be made of ceramic. If the base body 113a is made of ceramic, not only the reflective surface 113c may be a surface to which a silicon dioxide film or a double film made of a silicon dioxide film formed on a silver film is adhered, but also a ceramic surface with no film being adhered thereto.

If the silicon dioxide film is adhered to the reflective surface 113c, such a film may be formed by sputtering. In addition, the aluminum film or the silver film may be formed by vapor deposition.

The sealing resin section 114 includes a first sealing resin section (sealing layer) 114a and a second sealing resin section (resin layer) 114b. The first sealing resin section 114a is made of alkoxysilane resin, and is formed by curing a sealant represented by a composition formula of —(RnSiO_{(4-n)/2)}m- (where “R” is an alkyl group, “n” is 1, and “m” is an integer). The first sealing resin section 114a seals the entirety of the light emitting element 112. The first sealing resin section 114a contains silicon dioxide as a viscosity adjusting material.

In the present embodiment, the first sealing resin section 114a contains a phosphor 114x (not shown in FIG. 22) excited by light emitted from the light emitting element 112 to convert the wavelength of the light. The light emitting element 112 emits blue light. Thus, if the phosphor 114x emits yellow light, i.e., light having a complementary color of blue, the blue light and the yellow light are mixed, and white light can be emitted from the first sealing resin section 114a. As the phosphor 114x, a rare-earth doped nitride phosphor or a rare-earth doped oxide phosphor is preferred. More specifically, e.g., rare-earth doped alkaline-earth metal sulfide, rare-earth doped garnet of (Y.Sm)₃(Al.Ga)₅O₁₂:Ce or (Y_{0.39}Gd_{0.57}Ce_{0.03}Sm_{0.01})₃ Al₅O₁₂, rare-earth doped alkaline-earth metal orthosilicate, rare-earth doped thiogallate, or rare-earth doped aluminate is preferable. Alternatively, a silicate phosphor of (Sr_{1-a1-b2-x}Baₐ₁Ca_{b2}Euₓ)₂SiO₄ or an alpha-sialon phosphor of (α-sialon:Eu)Mx(Si, Al)₁₂(O, N)₁₆ may be used as the phosphor for emitting yellow light.

The second sealing resin section 114b is arranged on the first sealing resin section 114a as a cover layer, and is provided on the first sealing resin section 114a so as to be exposed to an outside of the color liquid crystal apparatus 100. The second sealing resin section 114b may be made of the same resin as the first sealing resin section 114a. However, the second sealing resin section 114b may be made of, e.g., silicone resin because a great change in volume of such resin is occurred when the resin is cured. When the second sealing resin section 114b is made of silicone resin, even if the silicone resin contains moisture because of hygroscopic properties thereof, the light emitting element 112 sealed by the first sealing resin section 114a is not susceptible to the moisture.

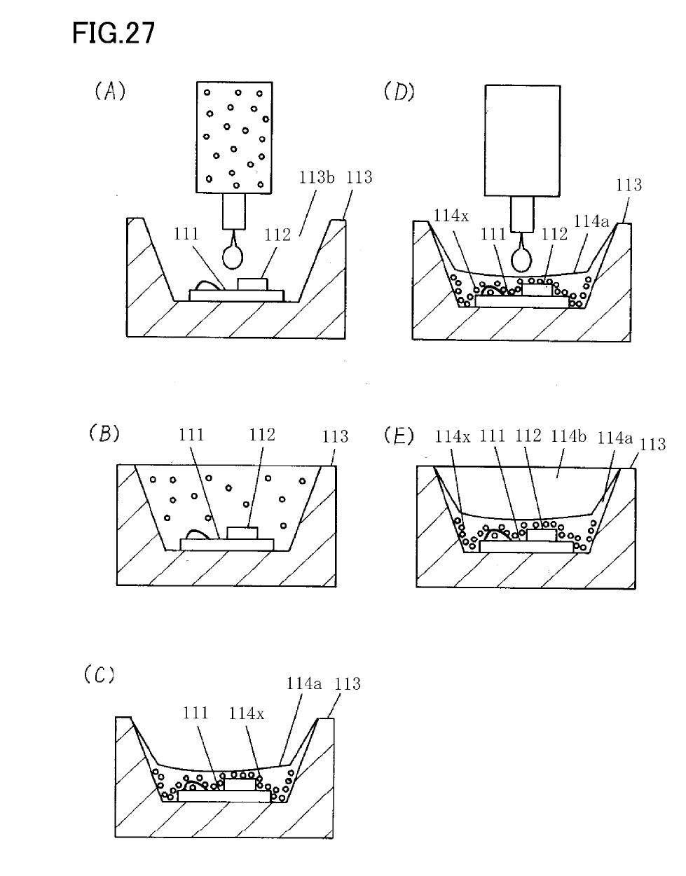

A method for manufacturing the light emitting device of the present embodiment configured as described above will be described with reference to FIG. 27. FIGS. 27(A)-27(E) are views illustrating steps for manufacturing the light emitting device illustrated in FIG. 22.

First, a mounting step is performed, at which a light emitting element 112 is mounted on a base 113 on which a protective element 111 is conductively mounted. Then, a sealing step is performed, at which a sealant containing a phosphor is dropped onto a recess 113b of the base 113 on which the protective element 111 and the light emitting element 112 are mounted and the recess 113b is filled with the sealant (see FIG. 27(A)).

Next, the base 113 filled with the sealant is placed in a heating furnace, and the sealant is cured (see FIG. 27(B)). The sealant is made of alkoxysilane resin dissolved in a solvent. Thus, when the sealant is cured, the solvent is volatilized, and the volume of the sealant is significantly reduced (see FIG. 27(C)).

The volume of the sealant formed into a first sealing resin section 114a is reduced in association with the curing of the sealant, and therefore dispersed particles of the phosphor 114x can be gathered close to the light emitting element 112. For example, if phosphor particles are uniformly dispersed across the entirety of the sealing resin section 114, phosphor particles positioned in an upper part of the sealing resin section 114 are apart from the light emitting element 112. Thus, light having emission intensity reduced while the light travels in the sealing resin section 114 reaches such phosphor particles. However, in the first sealing resin section 114a formed by reducing the volume of the sealant, since the particles of the phosphor 114x can be gathered around the light emitting element 112, light emitted from the light emitting element 112 can reach the phosphor 114x with little attenuation. Thus, light emitted from the light emitting element 112 can efficiently reach the phosphor 114x with a low degree of attenuation.

When the first sealing resin section 114a is formed as described above, part of the recess 113b extending from the first sealing resin section 114a to an opening plane of the recess 113b is filled with, e.g., silicone resin by potting (see FIG. 27(D)).

The part of the recess 113b is filled with the silicone resin, and the silicone resin is cured. In such a manner, a second sealing resin section 114b is formed (see FIG. 27(E)). Since the sealant forming the first sealing resin section 114a is in a state in which alkoxysilane resin is dissolved in the solvent, the solvent is volatilized in association with the curing of the sealant, and a great change in volume of the sealant is occurred. However, a resin material is dropped onto the first sealing resin section 114a and is cured, and the second sealing resin section 114b is formed. In such a manner, the lost volume can be compensated.

Since the silicone resin is not dissolved in a volatile solvent, a small change in volume of the silicone resin is occurred even by thermal curing. Thus, the recess 113b is filled with the silicone resin until the silicone resin reaches the opening plane of the recess 113b, and therefore an upper surface of the base 113 and an upper surface of the second sealing resin section 114b can be in substantially the same plane. As a result, even when a light emitting device 100 is delivered by a collet, a smooth adsorption surface can be defined at the top of the light emitting device 100.

As described above, in the light emitting device 100 of the present embodiment, since the sealant forming the first sealing resin section 114a is resin represented by a composition formula of —(RnSiO_{(4-n)/2)}m- (where “R” is an alkyl group, “n” is 1, and “m” is an integer), yellowing or blacking due to deterioration of the first sealing resin section 114a is not caused even when large current is applied to the high-brightness light emitting element 112, and the light emitting element 112 can continuously light up.

### Fourth Embodiment

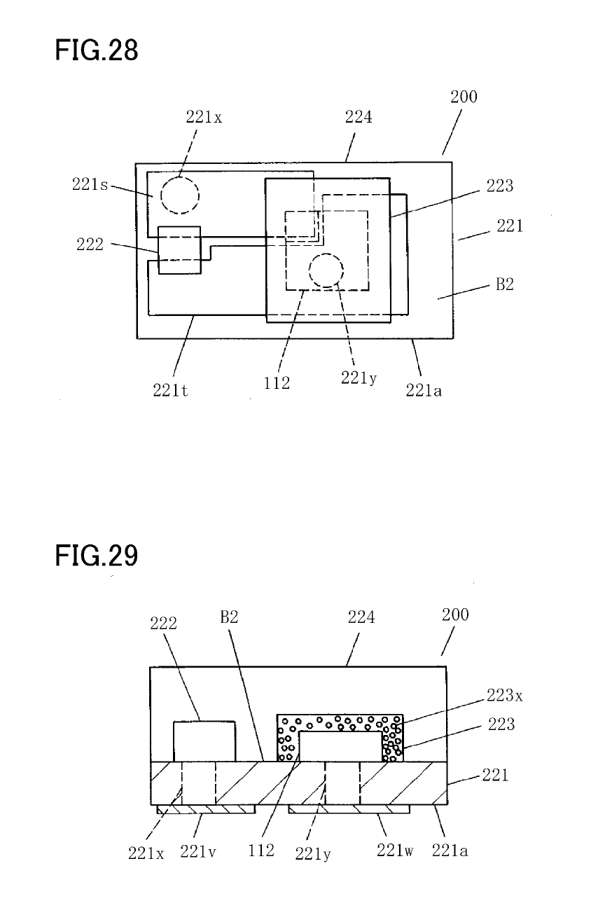

A light emitting device of a fourth embodiment will be described with reference to FIGS. 28 and 29. FIG. 28 is a plan view illustrating the light emitting device of the present embodiment. FIG. 29 is a cross-sectional view of the light emitting device illustrated in FIG. 28. In the present embodiment, a light emitting element having the same configuration as that of the light emitting element illustrated in FIGS. 22 and 23 can be used. Thus, the same reference numerals as those shown in FIGS. 22 and 23 are used to represent equivalent elements in FIGS. 28 and 29, and the description thereof will not be repeated.

In a light emitting device 200 illustrated in FIGS. 28 and 29, a protective element 222 and a light emitting element 112 are mounted on a base 221 which is a rectangular printed circuit board. A bottom cathode electrode 221v and a bottom anode electrode 221w which are made of a metal film are provided on a bottom surface of a ceramic base body 221a of the base 221. The bottom cathode electrode 221v is conductively connected to an upper cathode electrode 221s provided on a mounting surface B2 of the base body 221a on which the protective element 222 and the light emitting element 112 are mounted, through a through-hole wire 221x. In addition, the bottom anode electrode 221w is conductively connected to an upper anode electrode 221t provided on the mounting surface B2, through a through-hole wire 221y. Each of the protective element 222 and the light emitting element 112 extends over the upper cathode electrode 221s and the upper anode electrode 221t, and the protective element 222 and the light emitting element 112 are conductively connected together through the upper cathode electrode 221s and the upper anode electrode 221t such that the polarities, i.e., the anode and the cathode, of each of the protective element 222 and the light emitting element 112 correspond to the upper anode electrode 221t and the upper cathode electrode 221s, respectively.

The protective element 222 is a zener diode and has the same function as that of the protective element 111 (see FIGS. 22 and 23) used in the light emitting device of the third embodiment. The protective element 222 and the protective element 111 are different from each other in that an electrode (not shown in the figure) is provided on a bottom surface of the protective element 222 and the protective element 222 is connected to the light emitting element 112 through the upper cathode electrode 221s and the upper anode electrode 221t which are formed on the base 221.

The light emitting element 112 is sealed by a first sealing resin section 223. The light emitting element 112 sealed by the first sealing resin section 223 and the protective element 222 are together sealed by a second sealing resin section 224.

The first sealing resin section 223 is made of a sealant containing silicon dioxide (not shown in the figure), which is a viscosity adjusting material, and a phosphor 223x. As in the third embodiment, the sealant is made of alkoxysilane resin represented by a composition formula of —(RnSiO_{(4-n)/2)}m- (where “R” is an alkyl group, “n” is 1, and “m” is an integer).

The first sealing resin section 223 can be formed by screen printing as follows. After the light emitting element 112 is mounted on the base 221, a printing plate having an opening where a circumferential wall surrounding the light emitting element 112 will be formed is arranged. Then, the opening is filled with the sealant, and the sealant is leveled off by, e.g., a squeegee to mold the first sealing resin section 223.

An opening area of the printing plate is adjusted considering the degree of volume reduction.

The second sealing resin section 224 may be made of the same resin as the first sealing resin section 114a. However, as in the first embodiment, the second sealing resin section 224 may be made of, e.g., silicone resin because a great change in volume of the silicone resin is occurred in association with curing of the silicone resin.

The second sealing resin section 224 can be formed by the screen printing as follows. After the first sealing resin section 223 is formed, a printing plate having an opening where a circumferential wall surrounding the base 221 will be formed is arranged. Then, the opening is filled with resin, and such resin is leveled off by, e.g., the squeegee to mold the second sealing resin section 224.

In the light emitting device 200 including the base 221 which is the rectangular printed circuit board, since the first sealing resin section 223 for sealing the light emitting element 112 is formed by the sealant made of resin represented by a composition formula of —(RnSiO_{(4-n)/2)}m- (where “R” is an alkyl group, “n” is 1, and “m” is an integer), yellowing or blacking due to deterioration of the first sealing resin section 223 is not caused even when large current is applied to the high-brightness light emitting element 112, and the light emitting element 112 can continuously light up.

Even in a case where the first sealing resin section 223 is formed by the screen printing, the volume of the sealant is reduced in association with thermal curing of the sealant, and therefore the first sealing resin section 223 can be formed in a state in which particles of the phosphor 223x dispersed in the sealant are gathered around the light emitting element 112. Thus, light emitted from the light emitting element can efficiently reach the phosphor.

Although the embodiments have been described above, the present invention is not limited to such embodiments. For example, in the present embodiment, the sealing resin section has a double-layer structure of the first sealing resin section 114a or 223 and the second sealing resin section 114b or 224. However, if a resin layer on a side close to the light emitting element 112 is made of alkoxysilane resin, other resin material such as silicone resin may be used to form other resin layer, and one or more resin layers may be formed as necessary.

### INDUSTRIAL APPLICABILITY

Since the present invention relates to the light emitting device with less color unevenness, which includes the easily-formable sealing section containing the phosphor and sealing the light emitting element, the present invention is suitable for the light emitting device in which the phosphor is contained in the sealing section for sealing the light emitting element.

### DESCRIPTION OF REFERENCE CHARACTERS

1 Light Emitting Device
2 Light Emitting Element
3 Zener Diode
4 Wiring Substrate
5 Sealing Section
6 Light Reflective Section
7 Light Diffusion Section
10 Base Material
11 Phosphor Layer
12, 13, 15 Printing Plate
14 Reflective Layer
16 Light Diffusion Layer
21 Substrate
22 n-Type Layer
23 Active Layer
24 p-Type Layer
25 n-Side Electrode
26 p-Side Electrode
30 Polishing Machine
31 Cutting Machine
32 Dicer
41 Insulating Substrate
42 Wiring Pattern
42a Top Electrode
42b Bottom Electrode
42c Through-Hole Electrode
51 First Sealing Section
52 Second Sealing Section
100 Light Emitting Device
111 Protective Element
111a Upper Cathode Electrode
111b Upper Anode Electrode
112 Light Emitting Element
112a Substrate 112b n-Type Layer
112c Active Layer
112d p-Type Layer
112e n-Side Electrode
112f p-Side Electrode
113 Base
113a Base Body
113b Recess
113c Reflective Surface
113s Wiring Pattern
113t Die-Bonding Pattern
113v Bottom Cathode Electrode
113w Bottom Anode Electrode
113x Through-Hole Wire
113y Through-Hole Wire
114 Sealing Resin Section
114a First Sealing Resin Section
114b Second Sealing Resin Section
114x Phosphor
115 Wire
200 Light Emitting Device
221 Base
221a Base Body
221s Upper Cathode Electrode
221t Upper Anode Electrode
221v Bottom Cathode Electrode
221w Bottom Anode Electrode
221x Through-Hole Wire
221y Through-Hole Wire
222 Protective Element
223 First Sealing Resin Section
223x Phosphor
224 Second Sealing Resin Section

1. A light emitting device, comprising:
a light emitting element mounted on a base; and
a sealing section configured to seal the light emitting element and containing a phosphor,
wherein a light diffusion section containing particles for diffusing light emitted from the light emitting element is provided on the sealing section, and
the sealing section is formed such that a thickness of the sealing section in a sideward direction of the light emitting element is larger than a thickness of the sealing section in an upward direction of the light emitting element.

2. The light emitting device of claim 1, wherein
the light emitting element is an element for emitting blue light.

3. The light emitting device of claim 1, wherein
in the light diffusion section, silicone dioxide which is a diffusing material is contained in a transparent medium which is a base material.

4. The light emitting device of claim 1, wherein
a light reflective section configured to reflect light emitted from the light emitting element is provided so as to cover part of the sealing section other than a top surface of the sealing section, and
in the light reflective section, titanium dioxide which is a reflective material is contained in a transparent medium which is a base material.

5. The light emitting device of claim 1, wherein
the sealing section is made of resin represented by a composition formula of —(RnSiO_{(4-n)/2)}m-, where R is an alkyl group, n is 1 and m is an integer.

6. The light emitting device of claim 2, further comprising:
a phosphor contained in the sealing section and excited by blue light to emit orange light; and
a phosphor contained in the sealing section and configured to emit red light as an adjusting material for adjusting a color mixture of the blue light and the orange light.

7. The light emitting device of claim 6, wherein
the phosphor configured to emit orange light is a phosphor made of any one of (Ba, Sr)₂SiO₄:Eu²⁺, (Sr, Ca)₂SiO₄:Eu²⁺, (Ba, Sr, Ca)₂SiO₄:Eu²⁺, (Ba, Sr, Mg)₂SiO₄:Eu²⁺, (Sr, Eu²⁺, Yb)OSiO₂, Sr₃SiO₅:Eu²⁺, Y₃Al₅O₁₂:Ce, Y₃(Al, Ga)₅O₁₂:Ce³⁺, or Y₃(Al, Gd)₅O₁₂:Ce³⁺, or a combination thereof.

8. The light emitting device of claim 6, wherein
the phosphor configured to emit red light is a phosphor made of any one of CaAlSiN₃:Eu²⁺, (Sr, Ca)AlSiN₃:Eu²⁺, or Sr₂Si₅N₈:Eu²⁺, or a combination thereof.

9. The light emitting device of claim 1, wherein
the sealing section includes first and second sealing sections,
the first sealing section contains a phosphor excited by inner light emitted from an inner side relative to the first sealing section to emit light having a dominant wavelength adjacent to a wavelength of the inner light, and
the second sealing section positioned on an outer side relative to the first sealing section contains a phosphor which has an emission wavelength longer than that of the phosphor contained in the first sealing section and which is excited by the inner light and light having a wavelength range in which a longer wavelength part of the inner light and a shorter wavelength part of light emitted from the first sealing section overlap with each other.

10. The light emitting device of claim 9, wherein
the light emitting element emits blue light,
the first sealing section receives the blue light from the light emitting element to emit green light, and
the second sealing section receives the blue light and the green light to emit red light.
